(19) United States
(12) Patent Application Publication
(10) Pub. No.: US 2026/0221208 A1
(43) Pub. Date: Jul. 30, 2026

(54) NAND CELL HAVING LARGE SUB-THRESHOLD SWING FOR IN-MEMORY COMPUTE

(71) Applicant: Sandisk Technologies, Inc., Milpitas, CA (US)

(72) Inventors: Wei Cao, Fremont, CA (US); Peng Zhang, San Jose, CA (US); Xiang Yang, Santa Clara, CA (US)

(73) Assignee: Sandisk Technologies, Inc., Milpitas, CA (US)

(21) Appl. No.: 19/041,824

(22) Filed: Jan. 30, 2025

(51) Int. Cl. G11C 27/00; H10B 43/27; H10B 43/35

(52) U.S. Cl. CPC G11C 27/005; H10B 43/27; H10B 43/35

(57) ABSTRACT

Technology for NAND memory cells having a large sub-threshold swing for in-memory compute. A NAND memory structure has alternating conductive layers and insulating layers. NAND strings extend perpendicularly through the alternating conducting layers and insulating layers. The NAND strings may be formed in memory holes that contain an insulating core, a channel, a tunnelling layer, a charge trap layer, and a blocking layer. The diameter of the insulating core and the combined thickness of the tunnelling layer, charge trap layer, and blocking layer may be sized to achieve a large sub-threshold swing in the NAND memory cells.

### BACKGROUND

The present disclosure relates to technology for in-memory computing.

Artificial neural networks are finding increasing usage in artificial intelligence and machine learning applications. In an artificial neural network, a set of inputs is propagated through one or more intermediate, or hidden, layers to generate an output. The layers connecting the input to the output are connected by sets of weights that are generated in a training or learning phase by determining a set of a mathematical manipulations to turn the input into the output, moving through the layers calculating the probability of each output. Once the weights are established, they can be used in the inference phase to determine the output from a set of inputs. Although such neural networks can provide highly accurate results, they are extremely computationally intensive, and the data transfers involved in reading the weights connecting the different layers out of memory and transferring these weights into the processing units of a processing unit can be quite intensive.

Multiply and accumulate (MAC) operations are a basic operation in the implementation of machine learning algorithms, such as artificial neural networks. Such operations typically involve extremely large amounts of data and large numbers of operations. As such, they are extremely computationally intensive, involving large numbers of data transfers and consuming large amounts of time and power. A basic operation for these computations is vector-matrix multiplication (or even more basically vector-vector multiplication). The result of the vector-matrix multiplication (VMM) is typically a vector. The result of the vector-vector multiplication is typically a scalar. The vector-vector multiplication may be referred to as a vector dot product or, more generally, as a vector inner product.

It has been proposed to perform operations such as MAC and VMM in a memory system, which may be referred to as in-memory compute. A memory system typically contains a memory structure having many memory cells and various control lines. The memory structure may be three-dimensional (3D). One type of 3D structure has non-volatile memory cells arranged as NAND strings. The 3D memory structure may be arranged into units that are commonly referred to as blocks. For example, a block in a NAND memory system contains many NAND strings. A NAND string contains memory cell transistors connected in series, a drain side select gate at one end, and a source side select gate at the other end. Each NAND string is associated with a bit line. Moreover, each bit line is typically associated with many NAND strings. During memory operations such as program and read it is typical to select one of the NAND strings connected to a particular bit line at a time. The other NAND strings connected to the particular bit line are typically disconnected from the particular bit line at that time. The block typically has many word lines that provide voltages to the control gates of the memory cell transistors. In some architectures, each word line connects to the control gate of one memory cell on each respective NAND string in the block.

Memory cells including, but not limited to, NAND memory cells have a transistor. The memory cell transistor may contain a charge-trapping layer capable of storing electrons. When a memory cell transistor is programmed, electrons are stored in the charge-trapping layer The threshold voltage (Vth) of a memory cell transistor is increased in proportion to the amount of stored charge.

It is well-known that transistors may be operated in different regions. For example, a metal-oxide-semiconductor field effect transistor (MOSFET) may be operated in a sub-threshold region, linear region, or saturation region. An NMOS FET operates in the sub-threshold region (also referred to as a “cutoff region”) when the gate-to-source voltage is less than Vth (V_{GS}<V_{TH}). A PMOS FET operates in the sub-threshold region when the absolute value of the gate-to-source voltage is less than the absolute value of the Vth (|V_{GS}|<|V_{TH}|).

An NMOS FET operates in the linear region when the gate-to-source voltage is greater than the Vth, providing that the drain to source voltage is less than or equal to the gate to source voltage minus the threshold voltage (V_{GS}≥V_{TH}; V_{DS}<V_{GS}−V_{TH}). A PMOS FET operates in linear region under similar conditions with respect to absolute values (|V_{GS}|≥|V_{TH}|; |V_{DS}|<|V_{GS}|−|V_{TH}|). An NMOS FET operates in the saturation region under the following conditions: (V_{GS}≥V_{TH}; V_{DS}≥V_{GS}−V_{TH}). A PMOS FET operates in saturation region under similar conditions with respect to absolute values (|V_{GS}|≥|V_{TH}|; |V_{DS}|≥|V_{GS}|−|V_{TH}|).

Challenges remain in designing an energy-efficient and high-speed system capable of MAC and VMM operations.

### BRIEF DESCRIPTION OF THE DRAWINGS

Like-numbered elements refer to common components in the different figures.

FIG. 1 is a block diagram depicting one embodiment of a memory system.

FIG. 2A is a block diagram of one embodiment of a memory die.

FIG. 2B is a block diagram of one embodiment of an integrated memory assembly.

FIGS. 3A and 3B depict different embodiments of integrated memory assemblies.

FIG. 3C is a block diagram depicting one embodiment of a portion of column control circuitry that contains a number of read/write circuits.

FIG. 4 is a perspective view of a portion of one example embodiment of a monolithic three dimensional memory structure.

FIG. 4A is a block diagram of one embodiment of a memory structure having two planes.

FIG. 4B is a block diagram depicting a top view of a portion of block of memory cells.

FIG. 4C depicts an embodiment of a stack showing a cross-sectional view along line AA of FIG. 4B.

FIG. 4D depicts a view of the region 445 of FIG. 4C.

FIG. 4E depicts a cross-sectional view of memory hole 432 region of FIG. 4D.

FIG. 4F is a schematic diagram of a portion of one embodiment of a block, depicting several NAND strings.

FIG. 5 is a flowchart describing one embodiment of a process for programming memory cells connected to a selected word line.

FIGS. 6A and 6B depict example of memory cells programming to target threshold voltage distributions.

FIG. 7 is a graph of memory cell current (Icell) versus control gate voltage (Vcg) for memory cells programmed to different Vth states.

FIG. 8 is a graph of memory cell current (Icell) versus control gate voltage (Vcg) for memory cells programmed to different current states (It states).

FIG. 9A is a graph of memory cell current (Icell) versus Vgs with an emphasis on the linear region of operation.

FIG. 9B is a graph of memory cell current versus Vgs for a number of It states in the linear region.

FIG. 10A is a graph of memory cell current (Icell) versus Vgs with an emphasis on the sub-threshold region of operation.

FIG. 10B is a graph of memory cell current versus Vgs for an embodiment of It states in the sub-threshold region.

FIG. 11A is a graph that illustrates the variance in current for a number of current states.

FIG. 11B is a graph of typical cell current versus Vgs for conventional NAND memory cells that are intended for use to store ECC codewords.

FIG. 11C is a graph of cell current versus sub-threshold swing.

FIG. 12 is a graph showing a relationship between the core dielectric and the thickness of the memory film capacitor dielectric.

FIG. 13 is a graph of Icell versus Vgs for several different thicknesses of the memory film capacitor dielectric.

FIG. 14 is a graph of sub-threshold slope versus thickness of the memory film capacitor dielectric.

FIG. 15 is a flowchart of an embodiment of a process of programing NAND memory cells for in-memory compute, followed by performing the in-memory compute.

FIG. 16A illustrates a simple example of a convolutional neural network (CNN).

FIG. 16B illustrates a simple example of fully connected layers in an artificial neural network.

FIGS. 17A and 17B illustrates some elements of an example of a transformer model of deep neural network (DNN).

FIG. 18A is a flowchart describing one embodiment of a process for training a neural network to generate a set of weights.

FIG. 18B is a flowchart describing one embodiment of a process for inference using a neural network.

FIG. 19 is a schematic representation of a convolution operation in a convolutional neural network.

FIG. 20 is a schematic representation of the use of matrix multiplication in a fully connected layer of an artificial neural network.

FIGS. 21 and 22 schematically illustrate vector-matrix multiplications, which are a basic computation unit of a deep neural network (DNN).

FIG. 23A illustrates an embodiment for the multiplication of a vector and a matrix using a 3D NAND structure in which the input vector is applied to the word lines.

FIG. 23B illustrates a timing based method for analog values matrix-vector multiplication.

FIG. 24 is a flowchart for an embodiment of operating a 3D NAND multiply and accumulate engine.

FIG. 25 depicts an example of how memory cells on two NAND strings may be used to store weights in calculation cell units.

FIG. 26 depicts an energy band diagram of a layers in conventional NAND memory cell.

FIG. 27 depicts an energy band diagram of a layers in an embodiment of a NAND memory cell.

FIG. 28 depicts an energy band diagram of a layers in another embodiment of a NAND memory cell.

FIG. 29 depicts an energy band diagram of a layers in still another embodiment of a NAND memory cell.

### DETAILED DESCRIPTION

Technology is disclosed for NAND memory cells having a large sub-threshold swing for in-memory compute. The NAND memory cells may be programmed to current states in order to store numerical values for in-memory compute. Some of the current states are in the sub-threshold region of NAND memory cell operation. It is also possible to program NAND memory cells to current states in the linear region of NAND memory cell operation. Operating the NAND memory cells in the sub-threshold region requires far less power and/or current than the linear region. However, there will be some variance between the actual current to which a particular NAND cell is programmed and the target current. Therefore, the actual currents of the NAND cells programmed to a particular current state will be spread over some distribution (referred to herein as a current distribution). The accuracy of in-memory compute may be negatively impacted by a wide current distribution. There are technical challenges in achieving a narrow current distribution, especially in the sub-threshold region. In an embodiment, the sub-threshold swing when operating the NAND memory cells at currents of the sub-threshold current states may be about 1000 millivolts per decade (mV/dec). Some conventional NAND memory cells have a sub-threshold swing of about 400 mV/dec. The larger sub-threshold swing helps achieve a narrow current distribution in the sub-threshold region thereby improving accuracy of in-memory compute. An embodiment of a NAND structure has a very low current to voltage sensitivity, which is beneficial for in-memory compute.

An embodiment includes an apparatus having a memory structure with alternating conductive layers and insulating layers. The conductive layers may serve as word lines and control lines. The memory structure has NAND strings extending perpendicularly through the alternating conducting layers and insulating layers. Each NAND string has NAND memory cell transistors. The NAND strings may be formed in memory holes that are filled with layers of memory cell films, as well as an insulating core. Each NAND string has the insulating core, a channel adjacent and surrounding the insulating core, a tunnelling layer adjacent and surrounding to the silicon channel, a charge trap layer adjacent and surrounding to the tunnelling layer, and a blocking layer adjacent and surrounding to the charge trap layer. The blocking layer is adjacent to the alternating conducting layers and insulating layers. The combination of the tunnelling layer, the charge trap layer, and the blocking layer may function as the dielectric of a capacitor, with a word line being one capacitor plate and the channel being the other capacitor plate. Herein the term “memory cell capacitor” memory will be used to refer to a capacitor having the combination of the tunnelling layer, the charge trap layer, and the blocking layer as the dielectric of a capacitor, with a word line being one capacitor plate and the memory cell channel being the other capacitor plate. Herein, the term “cell capacitor dielectric” will be used to refer to the combination of the tunnelling layer, the charge trap layer, and the blocking layer. In an embodiment, the thickness of the cell capacitor dielectric and the diameter of the insulating core are sized to achieve a large sub-threshold swing in the NAND memory cells, which improves the gaps between the current states in the sub-threshold region. Increasing the thickness of the cell capacitor dielectric can help to achieve the large sub-threshold swing in the NAND memory cells. However, increasing the thickness of the cell capacitor dielectric can potentially decrease the memory cell capacitance. A lower memory cell capacitance leads to higher sensitivity to charge variance from a target charge for the memory cells, which can negatively impact the current state distributions in the sub-threshold region. In an embodiment, the diameter of the insulating core is made larger than would normally be necessary in the semiconductor fabrication process, which increases the memory cell capacitance to a more desirable level. In an embodiment, the cell capacitor dielectric thickness is at least 50 nanometers (nm) and the insulating core having a diameter of at least 150 nm. In an embodiment, a ratio of the cell capacitor dielectric thickness to the insulating core diameter is approximately 1:3.

Techniques for increasing the sub-threshold swing in the NAND memory cells may require an increase in programming voltage and/or erase voltage. For example, using a thicker cell capacitor dielectric may require an increase in programming voltage and/or erase voltage, absent any mitigation. In an embodiment, the tunnelling layer is modified from a conventional tunnelling layer to allow lower programming voltages and/or erase voltages. In an embodiment, a material with low potential energy barrier to the silicon NAND channel is used in the tunnelling layer. In one embodiment, the tunnelling layer has a single layer of SiONx that may be in direct contact with both the charge trap layer and the channel. In one embodiment, the tunnelling layer has a sub-layer of SiONx that may be in direct contact with the charge trap layer and a sub-layer of SiO₂ that may be in direct contact with the channel. In an embodiment, a material with a high dielectric constant (e.g., hafnium oxide) is used in the blocking layer. Using the material with a high dielectric constant (e.g., hafnium oxide) in the blocking layer causes more of the program (or erase) voltage to appear across the tunnelling layer, which allows a smaller program (or erase) voltage to be used.

Programming memory cell transistors to a current state may include applying a programming voltage to control gates of the respective memory cells transistor and then verifying currents of the respective memory cells. The verifying may include applying a verify reference voltage to the memory cell transistors and testing their respective currents with respect to a target current state. In an embodiment, the same verify reference voltage may be used for all current states.

In an embodiment, each current state represents a different numerical value. The programmed memory cells may be used in an in-memory compute such as, but not limited to, a multiply and accumulate (MAC). The various current states may be placed between a current noise floor and a saturation current. It is beneficial to fit a large number of current states within this window (the window including the sub-threshold region and the linear region). However, achieving narrow current distributions of the sub-threshold current states presents technical challenges.

In some embodiments, the memory cell transistors are programmed to allow for multiply and accumulate (MAC) or vector-matrix multiplication (VMM) operations. Multiply and accumulate (MAC) and vector-matrix multiplication (VMM) operations can be efficiently performed by in-memory compute operations. As one example, NAND memory cells are programmed to current states that represent weights of a matrix in, for example, an artificial neural network. For an in-memory compute, the memory system may apply voltages to the NAND strings on which the current state programmed memory cells reside, wherein these voltages represent an input vector. In an embodiment, the voltages that represent the input vector are applied to select gates of the NAND strings, while the verify voltage is applied to the control gates of the memory cells. In an embodiment, the voltages that represent the input vector are applied to the control gates of the memory cells, in which case the voltages applied to the control gates of the memory cells may be centered around the verify voltage. The memory cell currents are sensed and processed to determine results of the MAC. In-memory MAC multiplication can be implemented in both binary valued embodiments and analog or multi-bit embodiments. An embodiment includes a 3D NAND memory system that implement analog MAC blocks. 3D NAND memory system is scalable and has a compact footprint, which allows for massive artificial neural networks with billions of parameters.

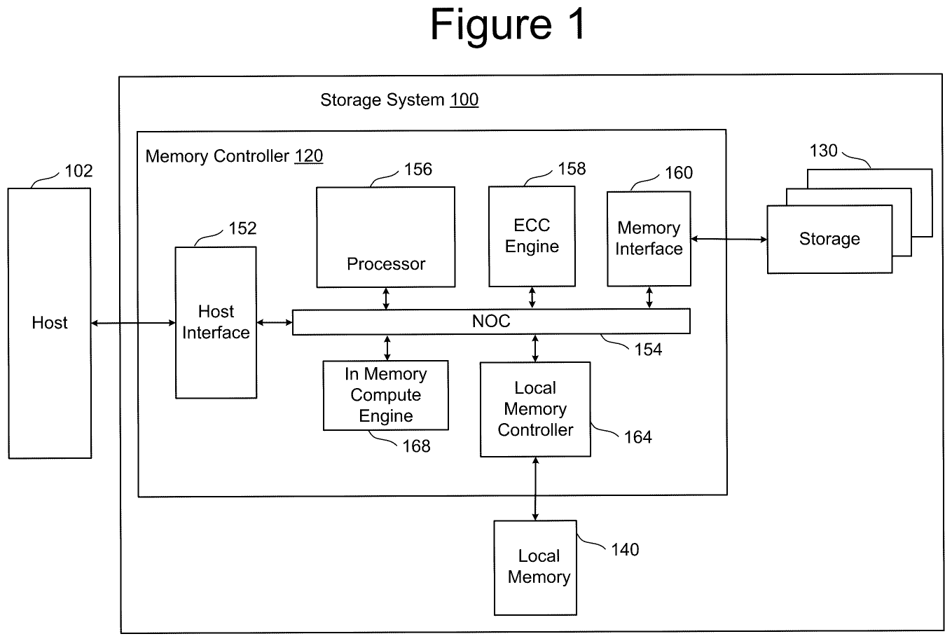

FIG. 1 is a block diagram of one embodiment of a memory system 100 that implements the technology described herein. In one embodiment, memory system 100 performs in-memory computing and may be referred to herein as a “computation device.” In an embodiment, storage 130 is used for in-memory compute. In one embodiment, memory system 100 is a solid state drive (“SSD”). Memory system 100 can also be a memory card, USB drive or other type of memory system. The proposed technology is not limited to any one type of memory system. Memory system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, memory system 100. In other embodiments, memory system 100 is embedded within host 102.

The components of memory system 100 depicted in FIG. 1 are electrical circuits. Memory system 100 includes a memory controller 120 (or storage controller) connected to non-volatile storage 130 and local high speed memory 140 (e.g., DRAM, SRAM, MRAM). Local memory 140 is non-transitory memory, which may include volatile memory or non-volatile memory. Local high speed memory 140 is used by memory controller 120 to perform certain operations. For example, local high speed memory 140 may store logical to physical address translation tables (“L2P tables”).

Memory controller 120 comprises a host interface 152 that is connected to and in communication with host 102. In one embodiment, host interface 152 implements an NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, and local memory controller 164. Local memory controller 164 is used to operate and communicate with local high speed memory 140 (e.g., DRAM, SRAM, MRAM).

ECC engine 158 performs error correction services. For example, ECC engine 158 performs data encoding and decoding. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156. In an embodiment in which memory controller 120 oversees in-memory compute in storage 130, the ECC engine 158 is not needed for data encoding and decoding.

Processor 156 performs the various controller memory operations such as programming, erasing, reading, and memory management processes. The in-memory compute engine 168 oversees in-memory compute in the storage 130 and/or local memory 140. The in-memory compute engine 168 may program weights of an AI model into memory cells in storage 130 and/or local memory 140. The in-memory compute engine 168 may provide input vectors to storage 130 and/or local memory during in-memory compute. The in-memory compute engine 168 may return computation results to the host 102. Although depicted as separated from the processor 156, the in-memory compute engine 168 may be implemented by the processor 156. In one embodiment, processor 156 is programmed by firmware. In other embodiments, processor 156 is a custom and dedicated hardware circuit without any software. In some embodiments, the storage 130 is used only for in-memory compute. In some embodiments, the storage 130 is used for both in-memory compute and host storage. The following describes an option to use a portion of storage for host storage. Processor 156 may also implement a translation module, as a software/firmware process or as a dedicated hardware circuit. In many systems, the non-volatile memory is addressed internally to the memory system using physical addresses associated with the one or more memory die. However, the host system will use logical addresses to address the various memory locations. This enables the host to assign data to consecutive logical addresses, while the memory system is free to store the data as it wishes among the locations of the one or more memory die. To implement this system, memory controller 120 (e.g., the translation module) performs address translation between the logical addresses used by the host and the physical addresses used by the memory die. One example implementation is to maintain tables (i.e., the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a memory system is so large that the local memory 140 cannot hold all of the L2P tables. In such a case, the entire set of L2P tables are stored in a storage 130 and a subset of the L2P tables are cached (L2P cache) in the local high speed memory 140.

Memory interface 160 communicates with non-volatile storage 130. In one embodiment, memory interface provides a Toggle Mode interface. Other interfaces can also be used. In some example implementations, memory interface 160 (or another portion of controller 120) implements a scheduler and buffer for transmitting data to and receiving data from one or more memory die.

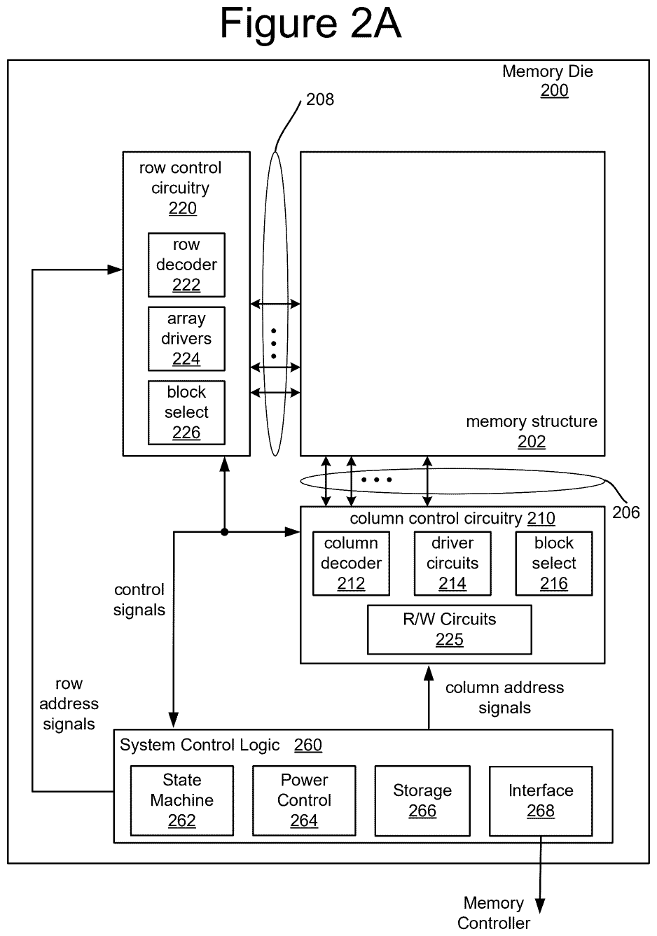

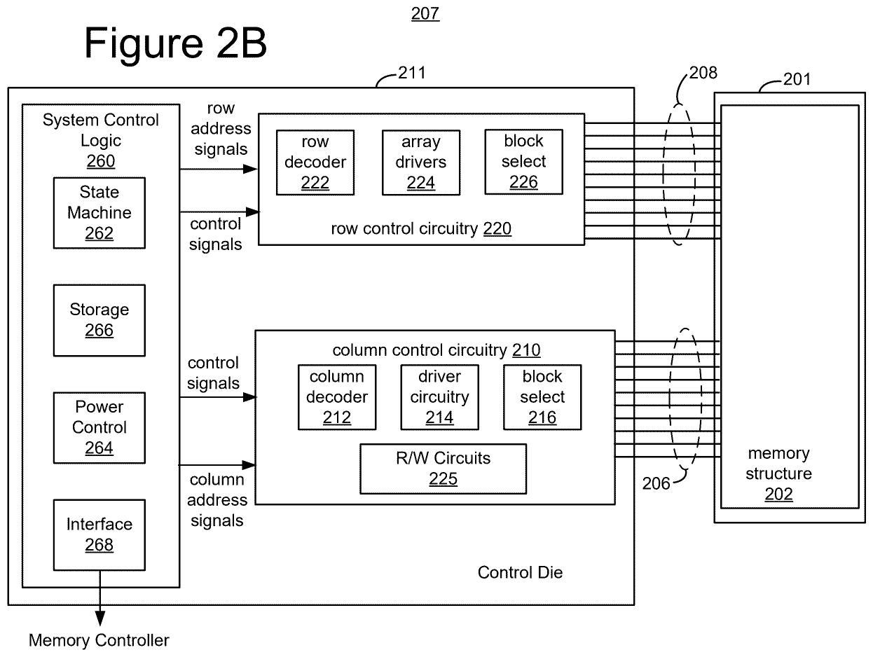

In one embodiment, non-volatile storage 130 comprises one or more memory dies. FIG. 2A is a functional block diagram of one embodiment of a memory die 200 that comprises non-volatile storage 130. Each of the one or more memory dies of non-volatile storage 130 can be implemented as memory die 200 of FIG. 2A. The components depicted in FIG. 2A are electrical circuits. Memory die 200 includes a memory structure 202 (e.g., memory array) that can comprise non-volatile memory cells (also referred to as non-volatile storage cells), as described in more detail below. The array terminal lines of memory structure 202 include the various layer(s) of word lines organized as rows, and the various layer(s) of bit lines organized as columns. However, other orientations can also be implemented. Memory die 200 includes row control circuitry 220, whose outputs are connected to respective word lines of the memory structure 202. Row control circuitry 220 receives a group of M row address signals and one or more various control signals from System Control Logic circuit 260, and typically may include such circuits as row decoders 222, array drivers 224, and block select circuitry 226 for both reading and writing (programming) operations. Row control circuitry 220 may also include read/write circuitry. Memory die 200 also includes column control circuitry 210 including read/write circuits 225. The read/write circuits 225 may contain sense amplifiers and data latches. The sense amplifier(s) input/outputs are connected to respective bit lines of the memory structure 202. Although only single block is shown for structure 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuitry 216, as well as read/write circuitry, and I/O multiplexers. The system control logic 260, column control circuitry 210, and/or row control circuitry 220 are configured to control memory operations such as open block reads at the die level.

System control logic 260 receives data and commands from memory controller 120 and provides output data and status to the host. In an embodiment the data includes weights of an AI model to program into memory cells in the memory structure 202. In an embodiment the output data includes computation results from an in-memory compute. In some embodiments, the system control logic 260 (which comprises one or more electrical circuits) includes state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations. System control logic 260 includes storage 266 (e.g., RAM, registers, latches, etc.), which may be used to store parameters for operating the memory structure 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die than the die that contains the memory structure 202.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of memory system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the memory system 100 is the amount of area to devote to the memory structure 202 and the amount of area to devote to the peripheral circuitry.

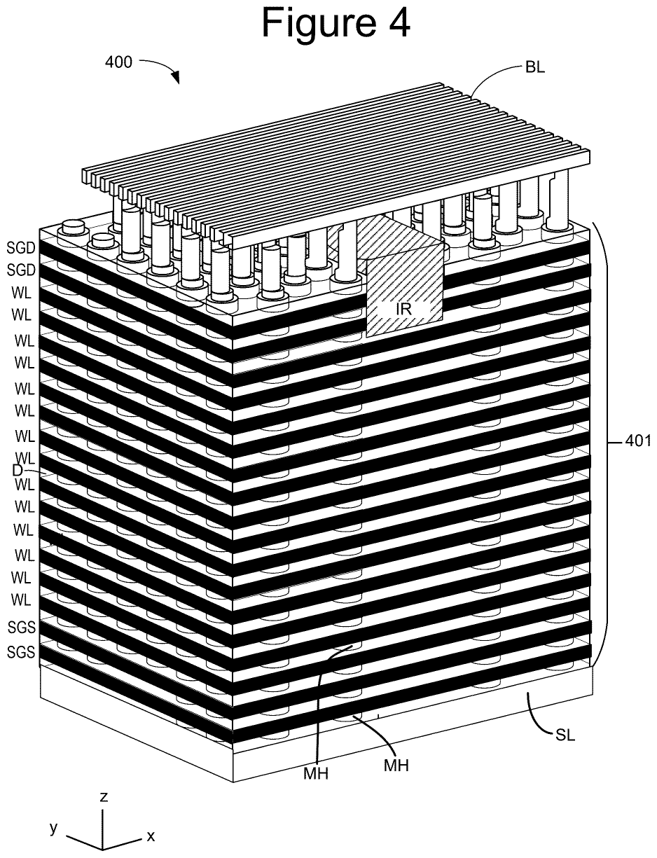

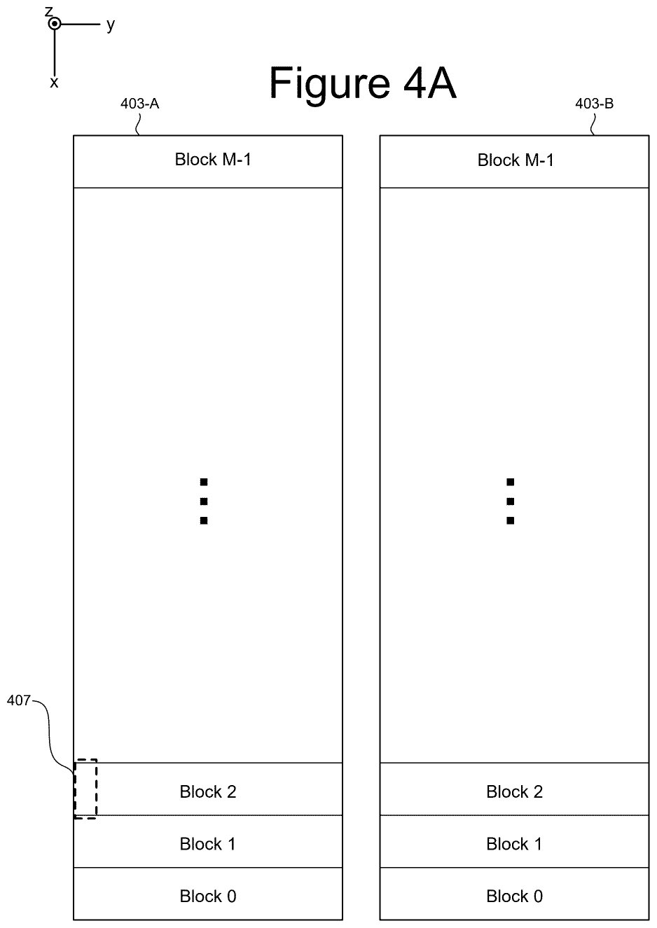

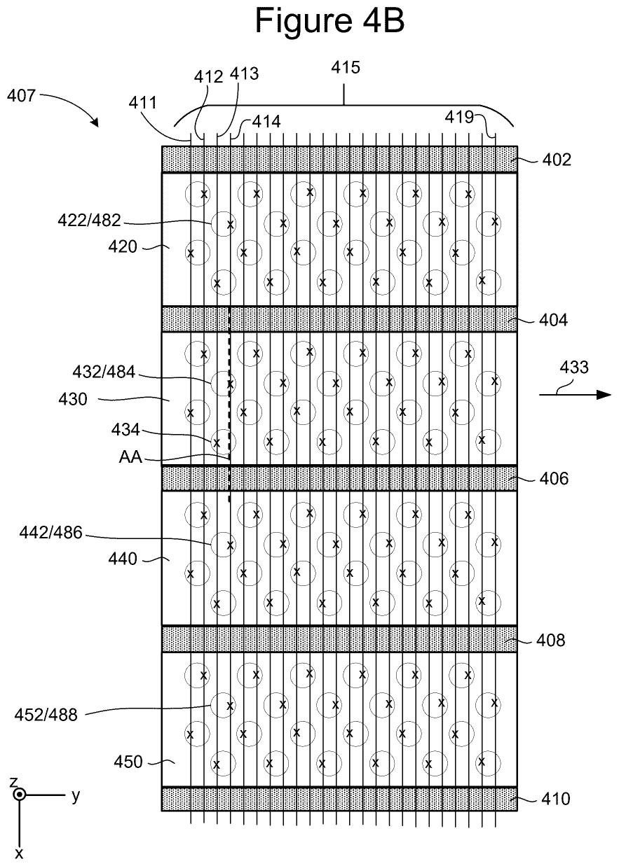

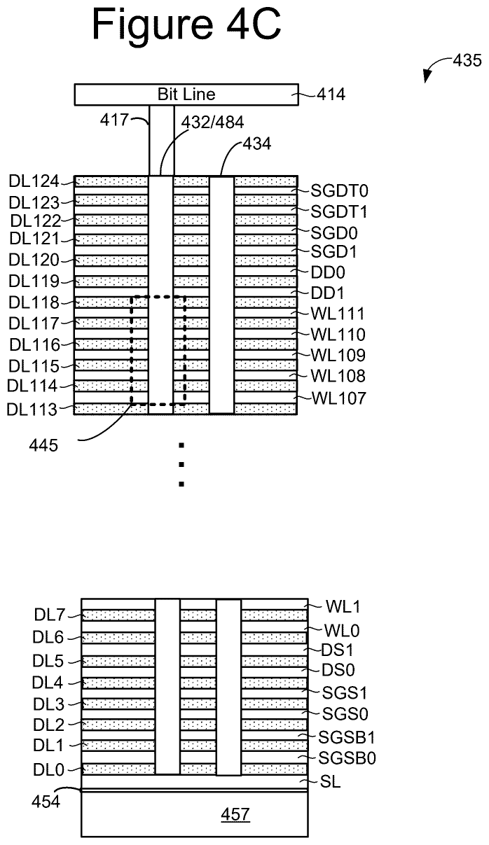

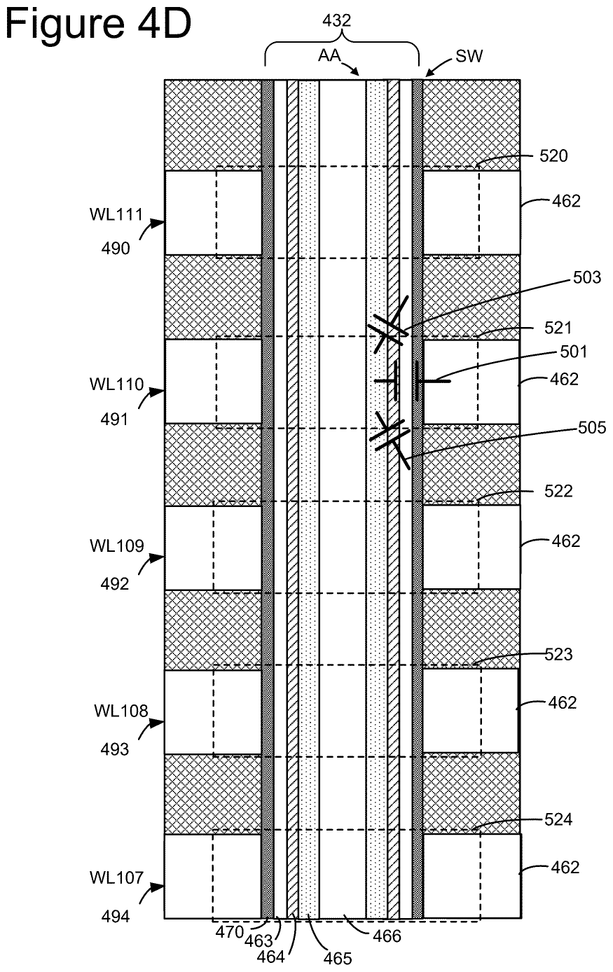

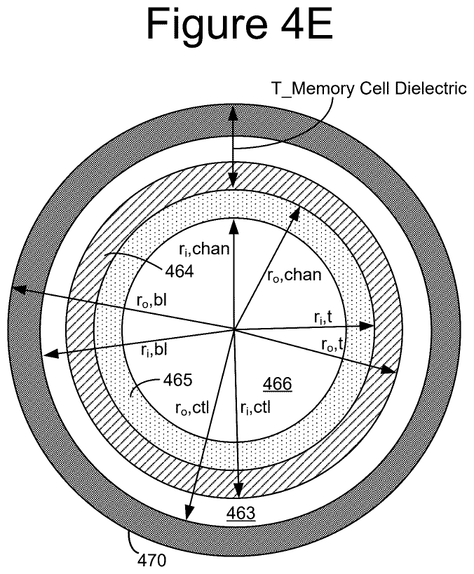

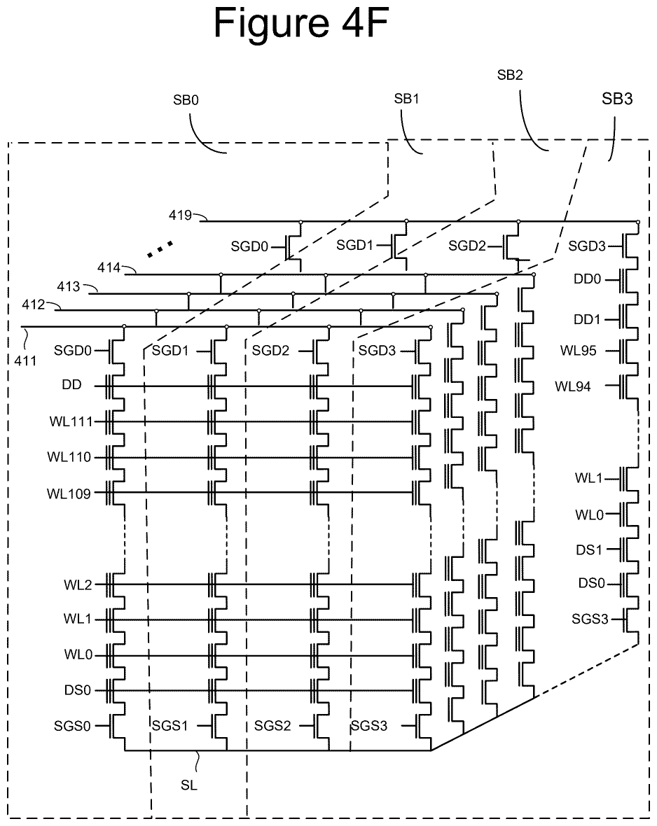

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies. Three-dimensional NAND structures (see, for example, FIG. 4) in particular may benefit from specialized processing operations.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more dies, such as two memory dies and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the non-volatile storage 130 of memory system 100. The integrated memory assembly 207 includes two types of semiconductor dies (or more succinctly, “die”). Memory structure die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory structure die 201. In some embodiments, the memory structure die 201 and the control die 211 are bonded together.

FIG. 2B shows an example of the peripheral circuitry, including control circuits, formed in a peripheral circuit or control die 211 coupled to memory structure 202 formed in memory structure die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory structure die 201. In some embodiments, some of the circuitry in the system control logic 260 is located on the on the memory structure die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate controller 120 may also be used to fabricate system control logic 260, row control circuitry 220, and column control circuitry 210). Thus, while moving such circuits from a die such as memory structure die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including read/write circuits 225 on the control die 211 coupled to memory structure 202 on the memory structure die 201 through electrical paths 206. For example, electrical paths 206 may provide electrical connection between column decoder 212, driver circuitry 214, and block select 216 and bit lines of memory structure 202. Electrical paths may extend from column control circuitry 210 in control die 211 through pads on control die 211 that are bonded to corresponding pads of the memory structure die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select 226 are coupled to memory structure 202 through electrical paths 208. Each electrical path 208 may correspond to a word line, dummy word line, or select gate line. Additional electrical paths may also be provided between control die 211 and memory structure die 201.

For purposes of this document, the phrases “a control circuit” or “one or more control circuits” can include any one of or any combination of memory controller 120, all or a portion of system control logic 260, all or a portion of row control circuitry 220, all or a portion of column control circuitry 210, read/write circuits 225, sense amps, a microcontroller, a microprocessor, and/or other similar functioned circuits. A control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit.

For purposes of this document, the term “apparatus” can include, but is not limited to, one or more of, memory system 100, memory controller 120, storage 130, memory die 200, integrated memory assembly 207, and/or control die 211.

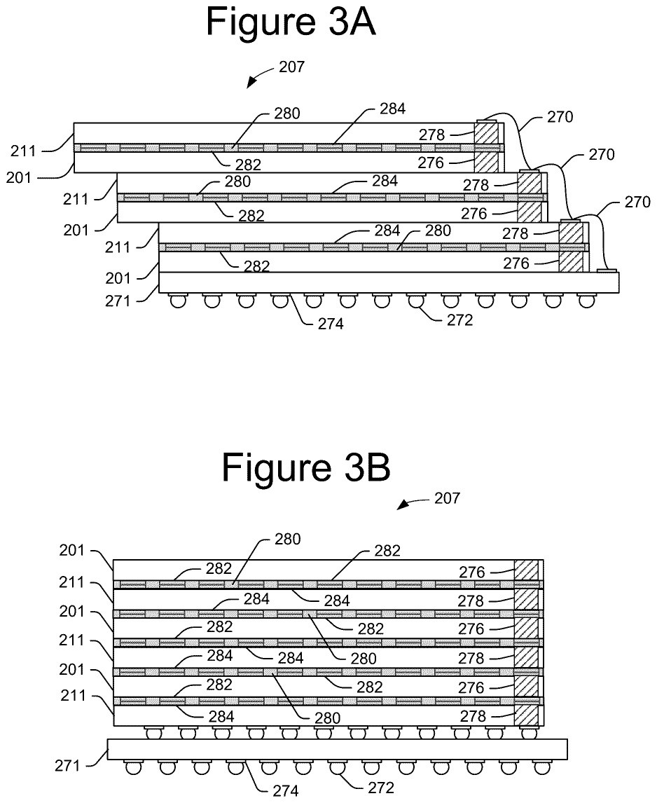

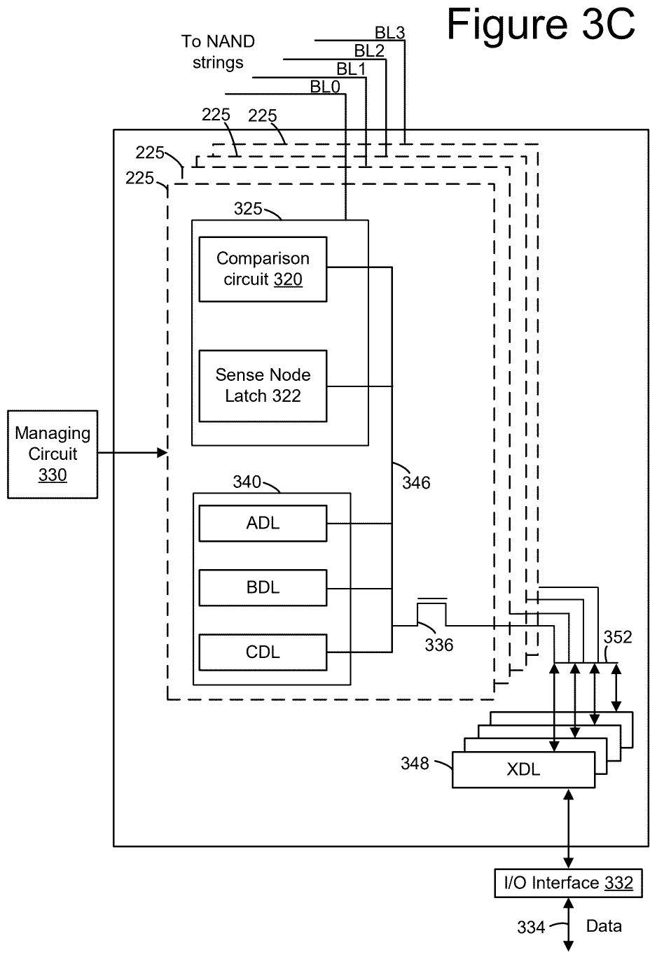

In some embodiments, there is more than one control die 211 and more than one memory structure die 201 in an integrated memory assembly 207. In some embodiments, the integrated memory assembly 207 includes a stack of multiple control dies 211 and multiple memory structure dies 201. FIG. 3A depicts a side view of an embodiment of an integrated memory assembly 207 stacked on a substrate 271 (e.g., a stack comprising control die 211 and memory structure die). The integrated memory assembly 207 has three control dies 211 and three memory structure dies 201. In some embodiments, there are more than three memory structure dies 201 and more than three control dies 211. In FIG. 3A there are an equal number of memory structure dies 201 and control dies 211; however, in one embodiment, there are more memory structure dies 201 than control dies 211. For example, one control die 211 could control multiple memory structure dies 201.

Each control die 211 is affixed (e.g., bonded) to at least one of the memory structure die 201. Some of the bond pads 282/284 are depicted. There may be many more bond pads. A space between two die 201, 211 that are bonded together is filled with a solid layer 280, which may be formed from epoxy or other resin or polymer. This solid layer 280 protects the electrical connections between the die 201, 211, and further secures the die together. Various materials may be used as solid layer 280.

The integrated memory assembly 207 may for example be stacked with a stepped offset, leaving the bond pads at each level uncovered and accessible from above. Wire bonds 270 connected to the bond pads connect the control die 211 to the substrate 271. A number of such wire bonds may be formed across the width of each control die 211 (i.e., into the page of FIG. 3A).

A memory die through silicon via (TSV) 276 may be used to route signals through a memory structure die 201. A control die through silicon via (TSV) 278 may be used to route signals through a control die 211. The TSVs 276, 278 may be formed before, during or after formation of the integrated circuits in the semiconductor dies 201, 211. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package. The solder balls 272 may form a part of the interface between integrated memory assembly 207 and memory controller 120.

FIG. 3B depicts a side view of another embodiment of an integrated memory assembly 207 stacked on a substrate 271. The integrated memory assembly 207 of FIG. 3B has three control dies 211 and three memory structure dies 201. In some embodiments, there are many more than three memory structure dies 201 and many more than three control dies 211. In this example, each control die 211 is bonded to at least one memory structure die 201. Optionally, a control die 211 may be bonded to two or more memory structure dies 201.

Some of the bond pads 282, 284 are depicted. There may be many more bond pads. A space between two dies 201, 211 that are bonded together is filled with a solid layer 280, which may be formed from epoxy or other resin or polymer. In contrast to the example in FIG. 3A, the integrated memory assembly 207 in FIG. 3B does not have a stepped offset. A memory die through silicon via (TSV) 276 may be used to route signals through a memory structure die 201. A control die through silicon via (TSV) 278 may be used to route signals through a control die 211.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package.

As has been briefly discussed above, the control die 211 and the memory structure die 201 may be bonded together. Bond pads on each die 201, 211 may be used to bond the two die together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat may also be applied. In embodiments using Cu-to-Cu bonding, the bond pads may be about 5 μm square and spaced from each other with a pitch of 5 μm to 5 μm. While this process is referred to herein as Cu-to-Cu bonding, this term may also apply even where the bond pads are formed of materials other than Cu.

When the area of bond pads is small, it may be difficult to bond the semiconductor dies together. The size of, and pitch between, bond pads may be further reduced by providing a film layer on the surfaces of the semiconductor die including the bond pads. The film layer is provided around the bond pads. When the die are brought together, the bond pads may bond to each other, and the film layers on the respective die may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller sizes and pitches.

Some embodiments may include a film on surface of the dies 201, 211. Where no such film is initially provided, a space between the die may be under filled with an epoxy or other resin or polymer. The under-fill material may be applied as a liquid which then hardens into a solid layer. This under-fill step protects the electrical connections between the dies 201, 211, and further secures the die together. Various materials may be used as under-fill material.

FIG. 3C is a block diagram depicting one embodiment of a portion of column control circuitry 210 that contains a number of read/write circuits 225. Each read/write circuit 225 is partitioned into a sense amplifier 325 and data latches 340. A managing circuit 330 controls the read/write circuits 225. The managing circuit 330 may communicate with state machine 262. In one embodiment, each sense amplifier 325 is connected to a respective bit line. Each bit line may be connected, at one point in time, to one of a large number of different NAND strings. A select gate on the NAND string may be used to connect the NAND string channel to the bit line.

Each sense amplifier 325 operates to provide voltages to one of the bit lines (see BL0, BL1, BL2, BL3) during program, verify, erase, read, and in-memory compute operations. Sense amplifiers are also used to sense the condition (e.g., data state) of a memory cell in a NAND string connected to the bit line that connects to the respective sense amplifier. The following will discuss use of the sense amplifier 325 to sense a condition (e.g., data state) of a memory cell. Sense amplifiers may also be used to sense bit line currents during in-memory compute (e.g., MAC, VMM). Such in-memory compute sense amplifiers may have a variety of implementations and are not limited to the example in FIG. 3C.

Each sense amplifier 325 may have a sense node. During sensing, a sense node is charged up to an initial voltage, Vsense_init, such as 3V. The sense node is then connected to the bit line for a sensing time, and an amount of decay of the sense node is used to determine whether a memory cell is in a conductive or non-conductive state. The amount of decay of the sense node also indicates whether a current Icell in the memory cell exceeds a reference current, Iref. A larger decay corresponds to a larger current. If Icell<=Iref, the memory cell is in a non-conductive state and if Icell>Iref, the memory cell is in a conductive state. In an embodiment, the sense node has a capacitor that is pre-charged and then discharged for the sensing time.

In particular, the comparison circuit 320 determines the amount of decay by comparing the sense node voltage to a trip voltage after the sensing time. If the sense node voltage decays below the trip voltage, Vtrip, the memory cell is in a conductive state and its Vth is at or below the verify voltage. If the sense node voltage does not decay below Vtrip, the memory cell is in a non-conductive state and its Vth is above the program verify voltage. A sense node latch 322 is set to 0 or 1, for example, by the comparison circuit 320 based on whether the memory cell is in a conductive or non-conductive state, respectively. The bit in the sense node latch 322 can also be used in a lockout scan to decide whether to set a bit line voltage to an inhibit or a program enable level in a next program loop. The bit in the sense node latch 322 can also be used in a lockout mode to decide whether to set a bit line voltage to a sense voltage or a lockout voltage in a read operation.

The data latches 340 are coupled to the sense amplifier 325 by a local data bus 346. The data latches 340 include three latches (ADL, BDL, CDL) for each sense amplifier 325 in this example. More or fewer than three latches may be included in the data latches 340. In one embodiment, for programming each data latch 340 is used to store one bit to be stored into a memory cell and for reading each data latch 340 is used to store one bit read from a memory cell. In a three bit per memory cell embodiment, ADL stores a bit for a lower page of data, BDL stores a bit for a middle page of data, CDL stores a bit for an upper page of data. Each read/write circuit 225 is connected to an XDL latch 348 by way of an XDL bus 352. In this example, transistor 336 connects local data bus 346 to XDL bus 352. An I/O interface 332 is connected to the XDL latches 348. The XDL latch 348 associated with a particular read/write circuit 225 serves as an interface latch for storing/latching data from the memory controller.

Managing circuit 330 performs computations, such as to determine the data stored in the sensed memory cell and store the determined data in the set of data latches. Each set of data latches 340 is used to store data bits determined by managing circuit 330 during a read operation, and to store data bits imported from the data bus 334 during a program operation which represent write data meant to be programmed into the memory. I/O interface 332 provides an interface between XDL latches 348 and the data bus 334.

During reading, the operation of the system is under the control of state machine 262 that controls the supply of different control gate voltages to the addressed memory cell. As it steps through the various predefined control gate voltages corresponding to the various memory states supported by the memory, the sense circuit may trip at one of these voltages and a corresponding output will be provided from the sense amplifier to managing circuit 330. At that point, managing circuit 330 determines the resultant memory state by consideration of the tripping event(s) of the sense circuit and the information about the applied control gate voltage from the state machine. It then computes a binary encoding for the memory state and stores the resultant data bits into data latches 340.

During program or verify operations for memory cells, the data to be programmed (write data) is stored in the set of data latches 340 from the data bus 334 by way of XDL latches 348. The program operation, under the control of the state machine 262, applies a series of programming voltage pulses to the control gates of the addressed memory cells. Each voltage pulse may be stepped up in magnitude from a previous program pulse by a step size in a process referred to as incremental step pulse programming. In one embodiment, each program voltage is followed by a verify operation to determine if the memory cells have been programmed to the desired memory state. In some cases, managing circuit 330 monitors the read back memory state relative to the desired memory state. When the two agree, managing circuit 330 sets the bit line in a program inhibit mode such as by updating its latches. This inhibits the memory cell coupled to the bit line from further programming even if additional program pulses are applied to its control gate.

FIG. 4 is a perspective view of a portion of one example embodiment of a monolithic three dimensional memory array/structure that can comprise memory structure 202, which includes a plurality non-volatile memory cells arranged as vertical NAND strings. For example, FIG. 4 shows a portion 400 of one block of memory. The structure depicted includes a set of bit lines BL positioned above a stack 401 of alternating dielectric layers and conductive layers. For example purposes, one of the dielectric layers is marked as D. The conductive layers are labeled as one of: SGD, WL, or SGS. An SGD conductive layer serves as drain side select lines. A WL conductive layer serves as a word line. An SGS conductive layer serves as a source side select line. The numbers of each of these conductive layers is limited for ease of illustration. The number of alternating dielectric layers and conductive layers can vary based on specific implementation requirements. Below the alternating dielectric layers and word line layers is a source line layer SL. Memory holes are formed in the stack of alternating dielectric layers and conductive layers. For example, one of the memory holes is marked as MH. Note that in FIG. 4, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three dimensional monolithic memory array that comprises memory structure 202 is provided below.

In one embodiment the block is operated as a number of “sub-blocks.” Each of these “sub-blocks” has many NAND strings. In an embodiment, an isolation region (IR) divides the SGD layers into multiple SGD select lines, each of which is used to select a sub-block (e.g., set of NAND strings). FIG. 4 depicts an example having one IR region and thereby two sub-blocks. However, there may be more than one IR region and thereby more than two sub-blocks. Optionally, the IR region can extend down through all of the alternating dielectric layers and conductive layers.

FIG. 4A is a block diagram explaining one example organization of memory structure 202, which is divided into two planes 403-A and 403-B. Each plane 403 is then divided into M physical blocks. In one example, each plane has about 2000 physical blocks (or more briefly “blocks”). However, different numbers of blocks and planes can also be used. In one “full-block” embodiment, a block of memory cells is a unit of erase. That is, all memory cells of a block are erased together. In a “sub-block mode” embodiment, blocks are divided into sub-blocks and the sub-blocks are the unit of erase. In an embodiment, a block contains a number of word lines with each sub-block containing a unique set of the data word lines. In an embodiment, each plane 403-A, 403-B has a set of bit lines that extend across all of the blocks in that plane. In an embodiment, one block per plane is selected at a time. Memory cells can also be grouped into blocks for other reasons, such as to organize the memory structure to enable the signaling and selection circuits. In some embodiments, a block represents a groups of connected memory cells as the memory cells of a block share a common set of word lines. For example, the word lines for a block are all connected to all of the vertical NAND strings for that block. Although FIG. 4A shows two planes 403-A, 403-B more or fewer than two planes can be implemented. In some embodiments, memory structure 202 includes four planes. In some embodiments, memory structure 202 includes eight planes. In some embodiments, programming can be performed in parallel in a first selected block in plane 403-A and a second selected block in plane 403-B.

FIGS. 4B-4F depict an example three dimensional (“3D”) NAND structure that corresponds to the structure of FIG. 4 and can be used to implement memory structure 202 of FIGS. 2A and 2B. FIG. 4B is a diagram depicting a top view of a portion 407 of Block 2. As can be seen from FIG. 4B, the physical block depicted in FIG. 4B extends in the direction of arrow 433. In one embodiment, the memory array has many layers; however, FIG. 4B only shows the top layer.

FIG. 4B depicts a plurality of circles that represent the vertical columns. Each of the vertical columns include multiple select transistors (also referred to as a select gate or selection gate) and multiple memory cells. In one embodiment, each vertical column implements a NAND string. For example, FIG. 4B depicts vertical columns 422, 432, 442, and 452. Vertical column 422 implements NAND string 482. Vertical column 432 implements NAND string 484. Vertical column 442 implements NAND string 486. Vertical column 452 implements NAND string 488. More details of the vertical columns are provided below. Since the physical block depicted in FIG. 4B extends in the direction of arrow 433, the physical block includes more vertical columns than depicted in FIG. 4B.

FIG. 4B also depicts a set of bit lines 415, including bit lines 411, 412, 413, 414, . . . 419. FIG. 4B shows twenty-four bit lines because only a portion of the physical block is depicted. It is contemplated that more than twenty-four bit lines connected to vertical columns of the physical block. Each of the circles representing vertical columns has an “x” to indicate its connection to one bit line. For example, bit line 414 is connected to vertical columns 422, 432, 442 and 452. The bit lines 415 may also extend over other blocks in the plane.

The physical block depicted in FIG. 4B includes a set of isolation regions 402, 404, 406, 408, and 410, which are formed of SiO₂; however, other dielectric materials can also be used. Isolation regions 402, 404, 406, 408, and 410 serve to divide the top layers of the physical block into four regions; for example, the top layer depicted in FIG. 4B is divided into regions 420, 430, 440, and 450, which are referred to herein as “sub-blocks.” Each sub-block contains a large number of NAND strings. In one embodiment, isolation regions 402 and 410 separate the physical block 407 from adjacent physical blocks. Thus, isolation regions 402 and 410 may extend down to the substrate. In one embodiment, the isolation regions 404, 406, and 408 only divide the layers used to implement select gates so that NAND strings in different sub-blocks can be independently selected. Referring back to FIG. 4, the IR region may correspond to any of isolation regions 404, 406, or 408. In one example implementation, a bit line only connects to one vertical column/NAND string in each of regions (sub-blocks) 420, 430, 440, and 450. In that implementation, each physical block has sixteen rows of active columns and each bit line connects to four NAND strings in each block. In one embodiment, all of the four vertical columns/NAND strings connected to a common bit line are connected to the same word line (or set of word lines); therefore, the system uses the drain side selection lines to choose one (or another subset) of the four to be subjected to a memory operation (program, verify, read, erase, and/or in-memory compute).

Although FIG. 4B shows each region (420, 430, 440, 450) having four rows of vertical columns, four regions (420, 430, 440, 450) and sixteen rows of vertical columns in a block, those exact numbers are an example implementation. Other embodiments may include more or fewer regions (420, 430, 440, 450) per block, more or fewer rows of vertical columns per region and more or fewer rows of vertical columns per block. FIG. 4B also shows the vertical columns being staggered. In other embodiments, different patterns of staggering can be used. In some embodiments, the vertical columns are not staggered.

FIG. 4C depicts an example of a stack 435 showing a cross-sectional view along line AA of FIG. 4B. The SGD layers include SGDT0, SGDT1, SGD0, and SGD1. The SGD layers may have more or fewer than four layers. The SGS layers includes SGSB0, SGSB1, SGS0, and SGS1. The SGS layers may have more or fewer than four layers. Six dummy word line layers DD0, DD1, WLIFDU, WLIDDL, DS1, and DS0 are provided, in addition to the data word line layers WL0-WL111. There may be more or fewer than 112 data word line layers and more or fewer than four dummy word line layers. Each NAND string has a drain side select gate at the SGD layers. Each NAND string has a source side select gate at the SGS layers. Also depicted are dielectric layers DL0-DL124.

Columns 432, 434 of memory cells are depicted in the multi-layer stack. The stack includes a substrate 457, an insulating film 454 on the substrate, and a portion of a source line SL. A portion of the bit line 414 is also depicted. Note that NAND string 484 is connected to the bit line 413. NAND string 484 has a source-end at a bottom of the stack and a drain-end at a top of the stack. The source-end is connected to the source line SL. A conductive via 417 connects the drain-end of NAND string 484 to the bit line 414. The channel of the NAND string 484 may be connected to or disconnected from the bit line 414 by operation of the drain side select gates (SGD).

In one embodiment, the memory cells are arranged in NAND strings. The word line layers WL0-WL111 connect to memory cells (also called data memory cells). Dummy word line layers DD0, DD1, DS0 and DS1 connect to dummy memory cells. A dummy memory cell does not store and is not eligible to store host data (data provided from the host, such as data from a user of the host), while a data memory cell is eligible to store host data. In some embodiments, data memory cells and dummy memory cells may have the same structure. Drain side select layers SGD are used to electrically connect and disconnect (or cut off) the channels of respective NAND strings from bit lines. Source side select layers SGS are used to electrically connect and disconnect (or cut off) the channels of respective NAND strings from the source line SL.

In some embodiments, the stack 435 is divided into two or more tiers. A two or other multi-tier stack can be used to form a relatively tall stack while maintaining a relatively narrow memory hole width (or diameter). After the layers of the lower tier are formed, memory hole portions are formed in the lower tier. Subsequently, after the layers of the upper tier are formed, memory hole portions are formed in the upper tier, aligned with the memory hole portions in the lower tier to form continuous memory holes from the bottom to the top of the stack. The resulting memory hole is narrower than would be the case if the hole were etched from the top to the bottom of the stack rather than in each tier individually. An interface (IF) region is created where the two tiers are connected. The IF region is typically thicker than the other dielectric layers. Due to the presence of the IF region, the adjacent word line layers suffer from edge effects such as difficulty in programming or erasing. These adjacent word line layers can therefore be set as dummy word lines. In some embodiments, the tiers are erased independent of one another. Hence, data may be maintained in the upper tier after the lower tiers is erased. Likewise, data may be maintained in the lower tier after the upper tier is erased.

FIG. 4D depicts a view of the region 445 of FIG. 4C. Data memory cell transistors 520, 521, 522, 523, and 524 are indicated by the dashed lines. A number of layers can be deposited along the sidewall (SW) of the memory hole 432 and/or within each word line layer, e.g., using atomic layer deposition. For example, each column (e.g., the pillar which is formed by the materials within a memory hole) can include a blocking oxide/block high-k material 470, charge-trapping layer or film 463 such as SiN or other nitride, a tunneling layer 464, a polysilicon body or channel 465, and a dielectric core 466. A word line layer can include a conductive metal 462 such as Tungsten as a control gate. For example, control gates 490, 491, 492, 493 and 494 are provided. In this example, all of the layers except the metal are provided in the memory hole. In other approaches, some of the layers can be in the control gate layer. Additional pillars are similarly formed in the different memory holes. A pillar can form a columnar active area (AA) of a NAND string.

When a data memory cell transistor is programmed, electrons are stored in a portion of the charge-trapping layer which is associated with the data memory cell transistor. These electrons are drawn into the charge-trapping layer from the channel, and through the tunneling layer. The Vth of a data memory cell transistor is increased in proportion to the amount of stored charge. During an erase operation, the electrons return to the channel.

Each of the memory holes can be filled with a plurality of annular layers (also referred to as memory film layers) comprising a blocking oxide layer, a charge trapping layer, a tunneling layer and a channel layer. A core region of each of the memory holes is filled with a body material, and the plurality of annular layers are between the core region and the WLLs in each of the memory holes. In some cases, the tunneling layer 464 can comprise multiple layers such as in an oxide-nitride-oxide configuration. In an embodiment, the tunneling layer 464 comprises a single layer. In an embodiment, the tunneling layer 464 comprises a material having a low potential energy barrier between the silicon channel and the silicon nitride charge trap layer 463. In one embodiment, the tunnelling layer 464 has a single layer of SiONx that may be in direct contact with both the charge trap layer 463 and the channel 465. In one embodiment, the tunnelling layer 464 has a sub-layer of SiONx that may be in direct contact with the charge trap layer 463 and a sub-layer of SiO₂ that may be in direct contact with the channel 465.

FIG. 4D depicts what is referred to herein as a “memory cell capacitor” 501 or “memory cell capacitance”. The combination of the tunneling layer 464, the charge-trapping layer 463, and the blocking oxide 470 functions as the dielectric of the memory cell capacitor 501 and is referred to herein as a “memory cell dielectric.” The word line (e.g., conductive metal 462) functions as one electrode of the memory cell capacitor 501 and the polysilicon body or channel 465 functions as one electrode of the memory cell capacitor 501. Also depicted a cell-to-cell capacitances 503, 505. The cell-to-cell capacitances 503, 505 may be referred to as fringing capacitances from the neighbor cell. The fringing capacitances 503, 505 from the neighbor cell may increase with an increase in the thickness of the memory cell dielectric (e.g., the combination of the tunneling layer 464, the charge-trapping layer 463, and the blocking oxide 470). Increasing the fringing capacitances 503, 505 may increase short channel effects, which may increase sub-threshold swing. The capacitance of the memory cell capacitor 501 impacts the Vth distribution (ΔVth). It is desirable to have a low Vth distribution to help achieve narrow Vth distributions. Equation 1 describes a relationship between the memory cell capacitance and the Vth distribution (ΔVth). Equation 1 also factors in distribution in the charge (ΔQ) stored in the memory cells.

$$Δ {V}_{th} = Δ Q / {C}_{Cell} \qquad Eq . 1$$

Equation 1 indicates that a higher memory cell capacitance C_{Cell} leads to a tighter Vth distribution (i.e., smaller ΔVth). Moreover, Equation 1 indicates that a smaller memory cell capacitance C_{Cell} results in a higher sensitivity to charge distribution (ΔQ). The charge distribution may result from, for example, various noises. Therefore, keeping the memory cell capacitance C_{Cell} higher can reduce the sensitivity to charge distribution (ΔQ) and thereby result in tighter Vth distributions, which is desirable.

FIG. 4E depicts a cross-sectional view of memory hole 432 region of FIG. 4D. The dielectric core 466 is at the center of the memory hole 432. The polysilicon body or channel 465 is adjacent to and surrounds the dielectric core 466. The tunneling layer 464 is adjacent to and surrounds the polysilicon body or channel 465. The charge-trapping layer 463 is adjacent to and surrounds the tunneling layer 464. The blocking oxide/block high-k material 470 is adjacent to and surrounds the charge-trapping layer 463. The blocking oxide/block high-k material 470 may be adjacent to and surrounded by either a conductive layer (e.g., word line) or insulating layer.

In an embodiment, the tunneling layer 464 comprises a single layer. In an embodiment, the tunneling layer 464 comprises a material having a low potential energy barrier between the silicon channel and the silicon nitride charge trap layer 463. In one embodiment, the tunnelling layer 464 has a single layer of SiONx that may be in direct contact with both the charge trap layer 463 and the channel 465. In one embodiment, the tunnelling layer 464 has a sub-layer of SiONx that may be in direct contact with the charge trap layer 463 and a sub-layer of SiO₂ that may be in direct contact with the channel 465. In an embodiment, a material with a high dielectric constant (e.g., hafnium oxide) is used in the blocking layer 470. Using the material with a high dielectric constant (e.g., hafnium oxide) in the blocking layer 470 layer causes more of the program (or erase) voltage to appear across the tunnelling layer, which allows a smaller program (or erase) voltage to be used. In an embodiment, hafnium oxide is the only material in the blocking layer 470.

The combination of the tunneling layer 464, the charge-trapping layer 463, and the blocking oxide 470 is referred to herein as a memory cell dielectric. The memory cell dielectric is the dielectric of a cylindrical “memory cell capacitor” that has a word line as one capacitor electrode and the polysilicon body or channel 465 as the other capacitor electrode. The thickness of the memory cell dielectric (T_Memory Cell Dielectric) impacts the sub-threshold swing of the NAND memory cells. Increasing T_Memory Cell Dielectric increases the sub-threshold swing of the NAND memory cells. The combination of the tunneling layer 464, the charge-trapping layer 463, and the blocking oxide 470 functions as a dielectric of a cylindrical capacitor, with one capacitor electrode being the polysilicon body 465 and the other capacitor electrode being a word line. The capacitance of this memory cell capacitor depends on the thickness of the memory cell dielectric (T_Memory Cell Dielectric) in accordance with the following Equations.

$${C}_{Memory Cell} = 1 / {\sum }_{k} \frac{1}{{c}_{k}} \qquad Eq . 2$$

$${C}_{Memory Cell} = 1 / {\sum }_{k} \frac{1}{{e}_{k}} ln ( \frac{{r}_{o , k}}{{r}_{i , k}} ) \qquad Eq . 3$$

Equation 2 indicates that the capacitance depends on the different layers in the memory cell dielectric. In FIG. 4E each layer (tunneling layer 464, the charge-trapping layer 463, and the blocking oxide 470) may have different characteristics including the relative permittivity (ε) and thickness. Equation 3 is based on well-known equation for capacitance of a cylindrical capacitor. Equation 3 refers to the inner radius (rᵢ) and the outer radius (rₒ) of each layer layers in the memory cell dielectric, each of which is depicted in FIG. 4E. The tunneling layer 465 has an inner radius of rᵢ,t and an inner radius of rₒ,t. The charge-trapping layer 463 has an inner radius of rᵢ,ctl and an inner radius of rₒ,ctl. The blocking oxide 470 has an inner radius of rᵢ,bl and an inner radius of rₒ,bl. Also depicted is the channel 465 having an inner radius of rᵢ,chan and an inner radius of rₒ, chan. In this example, the radius of the dielectric core 466 is the same as the inner radius (rᵢ,chan) of the channel 465. Equation 3 in general shows that increasing the outer radius without a change to the inner radius decreases the memory cell capacitance.

An embodiment of a NAND memory structure has a thicker memory cell dielectric to increase the sub-threshold swing of the NAND memory cells. The memory cell dielectric may be made thicker by increasing the outer radius of the memory cell dielectric layers without changing the diameter of the dielectric core 466. However, increasing the outer radius of the memory cell dielectric layers without changing the diameter of the dielectric core 466 will decrease the memory cell capacitance. Decreasing the memory cell capacitance has a negative impact on the gaps between the current states in the sub-threshold region. Increasing the diameter of the dielectric core 466 along with increasing the outer radius of the various memory cell dielectric layers provides for a substantial increase in sub-threshold swing in the NAND memory cells while keeping the memory cell capacitance at a target level. For example, the memory cell capacitance is kept sufficiently high to reduce the sensitivity to variance in charge stored in memory cells that are programmed to a particular current state or voltage state.

FIG. 4F is a schematic diagram of a portion of the memory array 202. FIG. 4F shows physical data word lines WL0-WL111 running across the entire block. The structure of FIG. 4F corresponds to a portion 407 in Block 2 of FIG. 4A, including bit lines 411, 412, 413, 414, . . . 419. Within the physical block, in one embodiment, each bit line is connected to four NAND strings. Thus, FIG. 4F shows bit line 411 connected to four NAND strings NS0, NAND string NS1, NAND string NS2, and NAND string NS3.

FIG. 4F shows an example in which there are four drain side select lines in the physical block. For example, drain side select line SGD0 may be used to select SB0, drain side select line SGD1 may be used to select SB1, drain side select line SGD2 may be used to select SB2, and drain side select line SGD3 may be used to select SB3. Although only drain side select line SGD0 is depicted per SB, there may be more than one drain side select line per SB. Each set drain side select lines connects to a group of NAND strings in the SB.

Although the example memories of FIGS. 4-4F are three dimensional memory structure that includes vertical NAND strings with charge-trapping material, other 3D memory structures can also be used with the technology described herein.

The memory systems discussed above can be erased, programmed and read. At the end of a successful programming process, the threshold voltages of the memory cells should be within one or more distributions of threshold voltages for programmed memory cells or within a distribution of threshold voltages for erased memory cells, as appropriate.

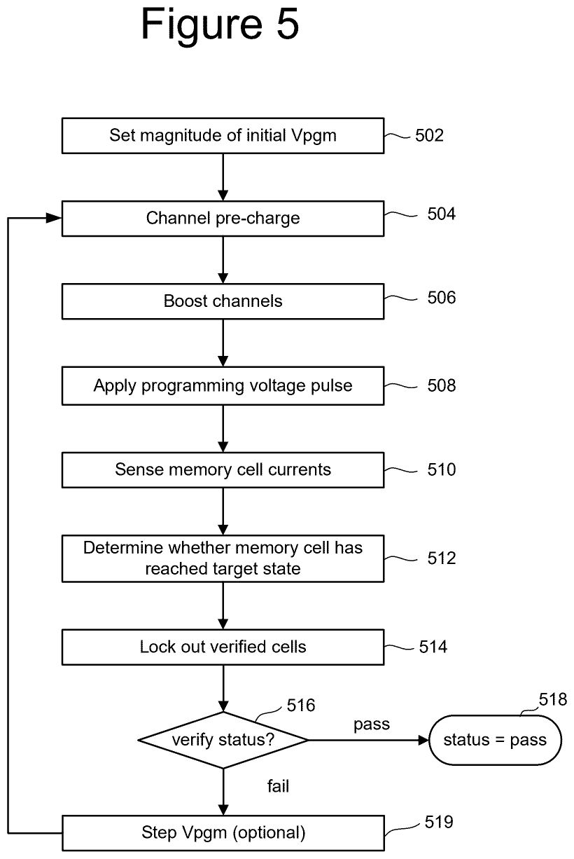

FIG. 5 is a flowchart describing one embodiment of a process for programming memory cells connected to a selected word line. Programming memory cells connected to a word line is referred to herein as programming the word line. For purposes of this document, the term program and programming are synonymous with write and writing. The process includes multiple loops, each of which includes a program phase and a verify phase. In an embodiment, the process is used to program weights of an AI model into the memory cells. In some techniques, the memory system determines a target current to which a memory cell transistor should be programmed, with an assumption of a particular verify voltage to be applied to the memory cell transistor to cause the memory cell current. For example, when programming weights of a neural network model, the memory system may determine a target current for a memory cell transistor (e.g., NAND memory cell).

In one example embodiment, the process in FIG. 5 is performed for memory structure 202 using the one or more control circuits (e.g., system control logic 260, column control circuitry 210, row control circuitry 220) discussed above. Typically, the program voltage applied to the control gates (via a selected data word line) during a program operation is applied as a series of program pulses (e.g., voltage pulses). Between programming pulses are a set of one or more verify pulses (e.g., voltage pulses) to perform verification. In many implementations, the magnitude of the program pulses is increased with each successive pulse by a predetermined step size. In step 502 of FIG. 5, the programming voltage signal (Vpgm) is initialized to the starting magnitude (e.g., ~12-16V or another suitable level). Optionally a program counter PC may be maintained by state machine 262 and initialized at 1. In one embodiment, the group of memory cells selected to be programmed (referred to herein as the selected memory cells) are programmed concurrently and are all connected to the same word line (the selected word line). There will likely be other memory cells that are not selected for programming (unselected memory cells) that are also connected to the selected word line. That is, the selected word line will also be connected to memory cells that are supposed to be inhibited from programming. Additionally, as memory cells reach their intended target state, they will be inhibited from further programming. Those NAND strings (e.g., unselected NAND strings) that include memory cells connected to the selected word line that are to be inhibited from programming have their channels boosted to inhibit programming.

When a channel has a boosted voltage, the voltage differential between the channel and the word line is not large enough to cause programming. To assist in the boosting, in step 504 the system will pre-charge channels of NAND strings that include memory cells connected to the selected word line that are to be inhibited from programming. In step 506, NAND strings that include memory cells connected to the selected word line that are to be inhibited from programming have their channels boosted to inhibit programming. Such NAND strings are referred to herein as “unselected NAND strings.” In one embodiment, at least some unselected word lines receive one or more boosting voltages (e.g., ~7-11 volts) to perform boosting schemes. A program inhibit voltage is applied to the bit lines coupled the unselected NAND string.

In step 508, a program voltage pulse of the programming voltage signal Vpgm is applied to the selected word line (the word line selected for programming). If a memory cell on a NAND string should be programmed, then the corresponding bit line is biased at a program enable voltage. In step 508, the program pulse is concurrently applied to all memory cells connected to the selected word line so that all of the memory cells connected to the selected word line are programmed concurrently (unless they are inhibited from programming). That is, they are programmed at the same time or during overlapping times (both of which are considered concurrent). In this manner all of the memory cells connected to the selected word line will concurrently have their threshold voltage change, unless they are inhibited from programming.

In step 510, memory cell currents are sensed via the respective bit lines. In an embodiment, the memory cell current is applied to a sense node such as a sense capacitor. The memory cell current may be applied to the sense node for a specific period of time referred to as a sense time (also referred to as an “integration time”). The sense node may be pre-charged to an initial voltage prior to discharging the sense node with the memory cell current for the sense time.
Step 512 includes a determination, for each cell being programmed, of whether the respective memory cell has reached its target state. The voltage on the sense node may be tested after the sense time to determine whether the memory cell has reached the target state. In one embodiment, the target state is a current state in which case step 512 may include a test of whether the memory cell current has reached (e.g., fallen to) a target current. In one embodiment, the target state is a Vth state in which case step 510 may include a test of whether the memory cell Vth has reached (e.g., increased to) a target Vth.

In step 514, a memory cell may be locked out after the memory cell has been verified (by a test of the Vth or It) that the memory cell has reached its target state. In an embodiment, when programming memory cells to currents to represent values such as weights a memory cell may be locked out when it reaches the target current for a verify reference voltage.

If, in step 516, it is determined that all of the memory cells have reached their target states (pass), the programming process is complete and successful because all selected memory cells were programmed and verified to their target states. A status of “PASS” is reported in step 518. Otherwise if, in step 516, it is determined that not all of the memory cells have reached their target states (fail), then the programming process continues to step 519. At step 519 the programming voltage signal Vpgm is optionally stepped up to the next magnitude. For example, the next pulse may have a magnitude greater than the previous pulse by a step size ΔVpgm (e.g., a step size of 0.1-1.0 volts). After step 519, the process loops back to step 504 and another program pulse is applied to the selected word line so that another iteration (steps 504-516) of the programming process of FIG. 5 is performed.

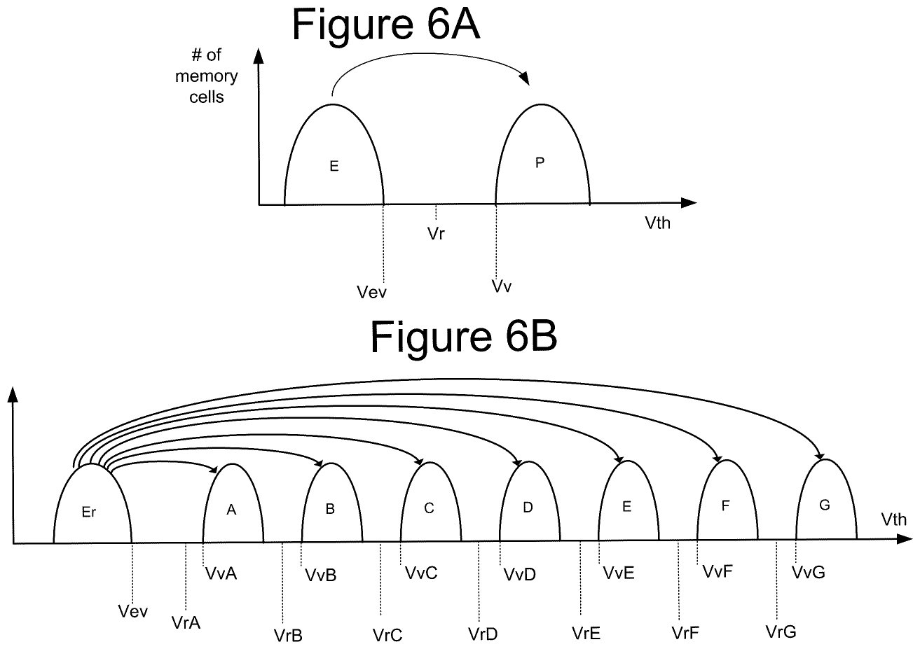

In an embodiment, some of the memory cells are used for in-memory compute in which case digital or analog values may be programmed into the memory cells. In an embodiment, the memory cells are programmed to current states to represent the numerical values. However, other memory cells may be used to store information as, for example, ECC codewords that are not used for in-memory compute. In an embodiment, the memory cells are programmed to target threshold voltages to store the ECC codewords. FIGS. 6A and 6B will be discussed as an example of programming memory cells to target threshold voltages. FIG. 6A is a graph of threshold voltage versus number of memory cells, and illustrates example threshold voltage distributions for the memory array when each memory cell stores one bit of data per memory cell. Memory cells that store one bit of data per memory cell data are referred to as single level cells (“SLC”). The data stored in SLC memory cells is referred to as SLC data; therefore, SLC data comprises one bit per memory cell. Data stored as one bit per memory cell is SLC data. FIG. 6A shows two threshold voltage distributions: E and P. Threshold voltage distribution E corresponds to an erased data state. Threshold voltage distribution P corresponds to a programmed data state. Memory cells that have threshold voltages in threshold voltage distribution E are, therefore, in the erased data state (e.g., they are erased). Memory cells that have threshold voltages in threshold voltage distribution P are, therefore, in the programmed data state (e.g., they are programmed). In one embodiment, erased memory cells store data “1” and programmed memory cells store data “0.” FIG. 6A depicts read reference voltage Vr. By testing (e.g., performing one or more sense operations) whether the threshold voltage of a given memory cell is above or below Vr, the system can determine whether a memory cells is erased (state E) or programmed (state P). FIG. 6A also depicts program verify reference voltage Vv. In some embodiments, when programming memory cells to data state P, the system will test whether those memory cells have a threshold voltage greater than or equal to Vv.

Memory cells that store multiple bit per memory cell data are referred to as multi-level cells (“MLC”). The data stored in MLC memory cells is referred to as MLC data; therefore, MLC data comprises multiple bits per memory cell. Data stored as multiple bits of data per memory cell is MLC data. In the example embodiment of FIG. 6B, each memory cell stores three bits of data. Other embodiments may use other data capacities per memory cell (e.g., such as two, four, or five bits of data per memory cell).

FIG. 6B shows eight threshold voltage distributions, corresponding to eight data states. The first threshold voltage distribution (data state) Er represents memory cells that are erased. The other seven threshold voltage distributions (data states) A-G represent memory cells that are programmed and, therefore, are also called programmed states. Each threshold voltage distribution (data state) corresponds to predetermined values for the set of data bits. The specific relationship between the data programmed into the memory cell and the threshold voltage levels of the cell depends upon the data encoding scheme adopted for the cells. In one embodiment, data values are assigned to the threshold voltage ranges using a Gray code assignment so that if the threshold voltage of a memory erroneously shifts to its neighboring physical state, only one bit will be affected. In an embodiment, the number of memory cells in each state is about the same.

FIG. 6B shows seven read reference voltages, VrA, VrB, VrC, VrD, VrE, VrF, and VrG for reading data from memory cells. By testing (e.g., performing sense operations) whether the threshold voltage of a given memory cell is above or below the seven read reference voltages, the system can determine what data state (i.e., A, B, C, D, . . . ) a memory cell is in. FIG. 6B also shows a number of verify reference voltages. The verify reference voltages are VvA, VvB, VvC, VVD, VvE, VvF, and VvG. In some embodiments, when programming memory cells to data state A, the system will test whether those memory cells have a threshold voltage greater than or equal to VvA. If the memory cell has a threshold voltage greater than or equal to VvA, then the memory cell is locked out from further programming. Similar reasoning applies to the other data states.

The memory cells that are programmed to the Vth distributions may be sensed (read or verify) using a number of techniques. One technique for sensing a NAND memory cell is to apply a reference voltage to the control gate of the NAND memory cell transistor and then connect the NAND memory cell to a sense node for a period of time referred to as a sense time or integration time. The sense node is charged to an initial voltage prior to connecting the NAND memory cell to the sense node. The memory cell current is allowed to discharge the sense node for the sense time. The voltage on the sense node is tested after the sense time to determine the state of the memory cell.

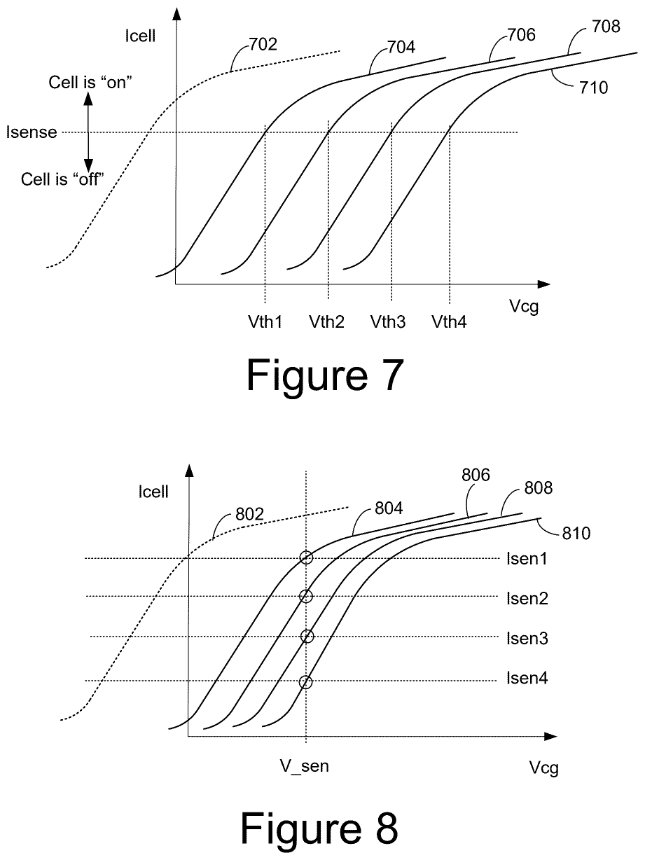

FIG. 7 is a graph of memory cell current (Icell) versus control gate voltage (Vcg) for memory cells programmed to different Vth states. Plot 702 is Icell versus Veg for the erase state. Plot 704 is Icell versus Veg for a first Vth state, which is centered at a threshold voltage of Vth1. Plot 706 is Icell versus Veg for a second Vth state, which is centered at a threshold voltage of Vth2. Plot 708 is Icell versus Veg for a third Vth state, which is centered at a threshold voltage of Vth3. Plot 710 is Icell versus Veg for a fourth Vth state, which is centered at a threshold voltage of Vth4. Referring back to FIG. 6B, the four Vth states could be four of the states between A-G. As noted above the memory cells may be sensed by applying a voltage to the control gate and allowing the memory cell current to discharge a sense node. In one technique, if the memory cell current is greater than Isense, then the memory cell is considered to be “on” or “conducting.” However, if the memory cell current is less than Isense, then the memory cell is considered to be “off” or “non-conducting.” A memory cell that is conducting is considered to have its Vth below the reference voltage applied to the control gate. A memory cell that is non-conducting is considered to have its Vth above the reference voltage applied to the control gate. Significantly, a different reference voltage is applied to the memory cells to test for each of the different Vth states.

In some embodiments, the memory cells are programmed to current states (instead of Vth states). Herein, “It” may be used to refer to a “current state.” Programming the memory cells to current states may include testing whether a memory cell has reached a target current for the current state (when the verify voltage is applied to the memory cell). In some techniques the memory cells are erased to a low Vth prior to programming such that the memory cell current decreases as charge is added to the charge trapping layer (with the assumption of the same magnitude verify voltage is used as programming proceeds). FIG. 8 is a graph of memory cell current (Icell) versus control gate voltage (Vcg) for memory cells programmed to different current states (It states). Plot 802 is Icell versus Vcg for erased cells prior to programming. Plot 804 is Icell versus Veg for a first It state. Plot 806 is Icell versus Vcg for a second It state. Plot 808 is Icell versus Vcg for a third It state. Plot 810 is Icell versus Veg for a fourth It state. To verify whether a particular memory cell has been programmed to its respective It state, the memory cell current may be sensed while applying a verify reference voltage to the control gate of the memory cell. In this example, the same verify reference voltage (V_sen) is used to verify all of the It states. The verification may include testing whether the memory cell's current is at the current for the target It state. Thus, there may be a separate target current for each It state. FIG. 8 shows a target current of Isen1 for the first It state, a target current of Isen2 for the second It state, a target current of Isen3 for the third It state, and a target current of Isen4 for the fourth It state. Therefore, memory cells to be programmed to the first It state have V_sen applied to the control gate and are tested with respect to Isen1, memory cells to be programmed to the second It state have V_sen applied to the control gate and are tested with respect to Isen2, memory cells to be programmed to the third It state have V_sen applied to the control gate and are tested with respect to Isen3, and memory cells to be programmed to the fourth It state have V_sen applied to the control gate and are tested with respect to Isen4.

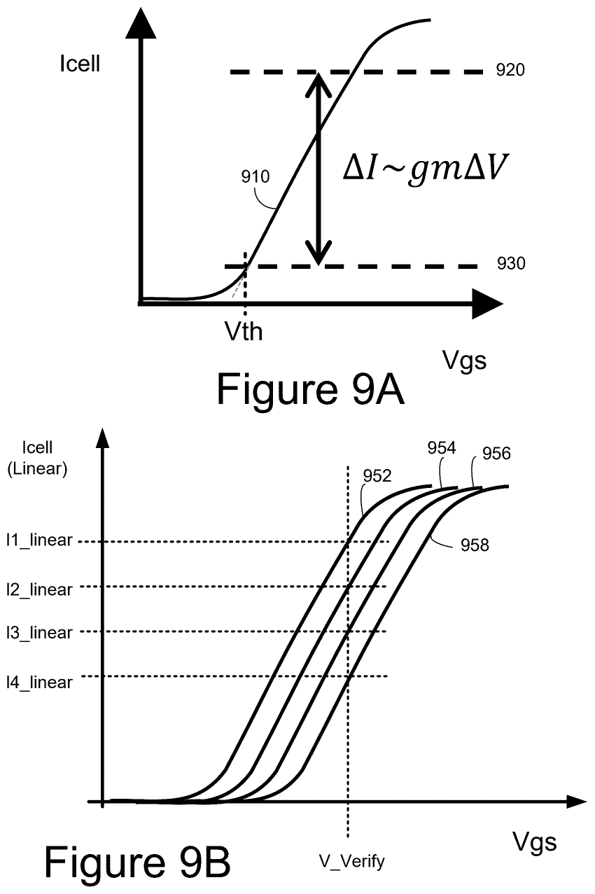

FIG. 9A is a graph of memory cell current (Icell) versus Vgs with an emphasis on the linear region of operation. Plot 910 shows Icell versus Vgs. Dotted lines 920, 930 mark boundaries of the linear region in which plot 910 is linear (or close to linear). As depicted, the linear region starts when Vgs is at or above Vth. The slope of plot 910 is approximately the transconductance of the memory cell transistor (gm). Therefore, the change in cell current is related to the change in control gate voltage as follows in Equation 4.

$$Δ {I}_{DS} ≅ gm Δ {V}_{GS} \qquad Eq . 4$$

Note that the change in cell current is linearly related to the change in Vgs.

FIG. 9B is a graph of memory cell current versus Vgs for a number of It states in the linear region. The y-axis is a linear scale for Icell. Four It states are depicted for the linear region, but there may be more than four It states in the linear region. For the memory cells that are programmed to one of the It states in the linear region, applying V_verify as Vgs will cause the memory cell to operate in the linear region. The four It states in the linear region may be spaced linearly in terms of the difference in current when V_verify in applied as Vgs. Plot 952 is Icell versus Vcg for a first It state in the linear region. Plot 954 is Icell versus Veg for a second It state in the linear region. Plot 956 is Icell versus Veg for a third It state in the linear region. Plot 958 is Icell versus Vcg for a fourth It state in the linear region.

FIG. 9B shows a target current of I1_linear for the first It state in the linear region, a target current of I2_linear for the second It state in the linear region, a target current of I3_linear for the third It state in the linear region, and a target current of I4_linear for the fourth It state in the linear region. Therefore, memory cells to be programmed to the first It state having V_Verify applied to the control gate and are tested with respect to I1_linear, memory cells to be programmed to the second It state having V_Verify applied to the control gate and are tested with respect to I2_linear, memory cells to be programmed to the third It state having V_Verify applied to the control gate and are tested with respect to I3_linear, and memory cells to be programmed to the fourth It state having V_Verify applied to the control gate and are tested with respect to I4_linear. Note that when programmed, the actual current of the memory cell transistor may be slightly higher or lower than the target current.

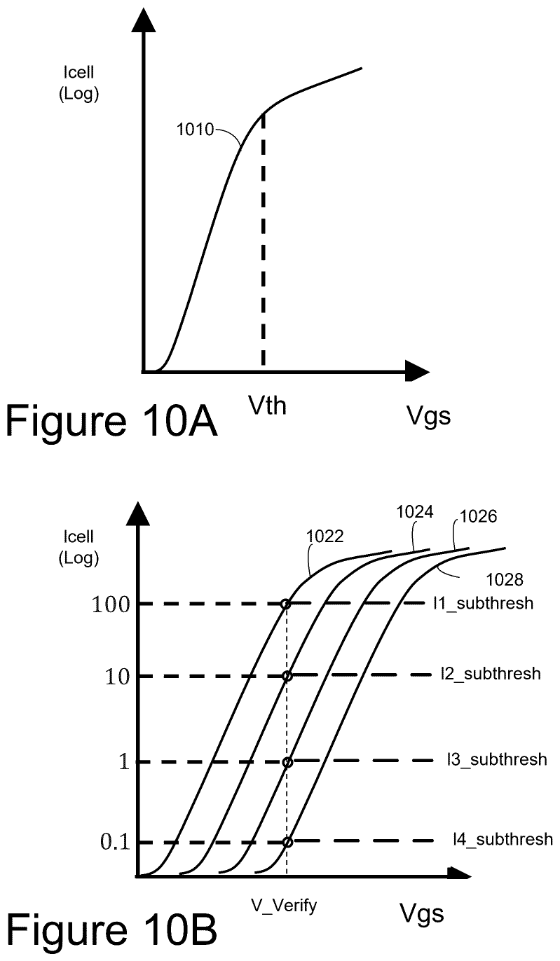

FIG. 10A is a graph of memory cell current (Icell) versus Vgs with an emphasis on the sub-threshold region of operation. Memory cell current (Icell) is on a log scale. Plot 1010 shows Icell versus Vgs. The sub-threshold region is where Vgs is below Vth. The linear region starts when Vgs is at or above Vth. In the sub-threshold region, the memory cell current (Icell) changes exponentially with changes in Vgs. Equation 5 describes an expression for memory cell transistor current in the sub-threshold region.

$${I}_{cell} = {I}_{0} exp ( \frac{{V}_{gs} - {V}_{th}}{m {ϕ}_{T}} ) \qquad Eq . 5$$

In Equation 5, φ_{T} represents a product of the Boltzmann constant and the temperature divided by elementary charge. Equation 6 describes an expression for m in Equation 4, where SS is the sub-threshold swing.

$$m = \frac{SS}{{ϕ}_{T} ln 10} \qquad Eq . 6$$

Therefore, from Equations 5 and 6, the Icell width (ΔIcell) can be seen as been exponential with respect to change in the Vgs, as indicated in Equation 7.

$$Δ {I}_{Cell} = \frac{{I}_{Cell}}{SS / ln 10} Δ {V}_{gs} \qquad Eq . 7$$

Equation 7 indicates that ΔI_{Cell} is a function of the current state, instead of roughly a constant. Moreover, as the sub-threshold swing (SS) is in the denominator, a larger sub-threshold swing results in a smaller (e.g., tighter) current distribution ΔIcell. A smaller ΔIcell allows for more sub-threshold current states, which is beneficial. A smaller ΔIcell helps increase in-memory compute accuracy. In one technique, the Icell state spacing is exponential in the subthreshold region. In one technique, the Icell state spacing is uniform in the linear region and exponential in the subthreshold region.

FIG. 10B is a graph of memory cell current versus Vgs for an embodiment of It states in the sub-threshold region. The y-axis is a log scale for Icell. Four It states are depicted for the sub-threshold region, but there may be more than four It states in the sub-threshold region. For the memory cells that are programmed to one of the It states in the sub-threshold region, applying V_verify as Vgs will cause the memory cell to operate in the sub-threshold region. In one technique, the four It states in the sub-threshold region are spaced exponentially in terms of the difference in current when V_verify in applied as Vgs. Plot 1022 is Icell versus Vgs for a first It state in the sub-threshold region. Plot 1024 is Icell versus Vgs for a second It state in the sub-threshold region. Plot 1026 is Icell versus Vgs for a third It state in the sub-threshold region. Plot 1028 is Icell versus Vgs for a fourth It state in the sub-threshold region.

FIG. 10B shows a target current of I1_subthresh for the first It state in the sub-threshold region, a target current of I2_subthresh for the second It state in the sub-threshold region, a target current of I3_subthresh for the third It state in the sub-threshold region, and a target current of I4_subthresh for the fourth It state in the sub-threshold region. Therefore, memory cells to be programmed to the first It state have V_Verify applied to the control gate and are tested with respect to I1_subthresh, memory cells to be programmed to the second It state have V_Verify applied to the control gate and are tested with respect to I2_subthresh, memory cells to be programmed to the third It state have V_Verify applied to the control gate and are tested with respect to I3_subthresh, and memory cells to be programmed to the fourth It state have V_Verify applied to the control gate and are tested with respect to I4_subthresh. The current spacing between the current states in the sub-threshold region may be exponential. In the example in FIG. 10B there is a factor of 10 between each adjacent current state in the sub-threshold region. Note that when programmed, the actual current of the memory cell may be slightly higher or lower than the target current, thereby resulting in a NAND cell current distribution for each current state.

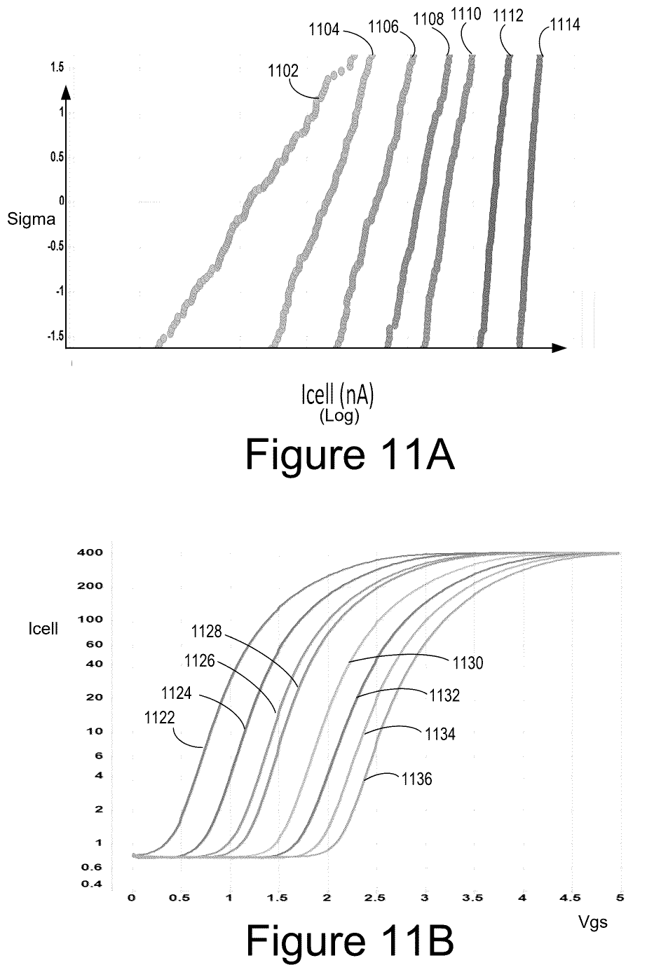

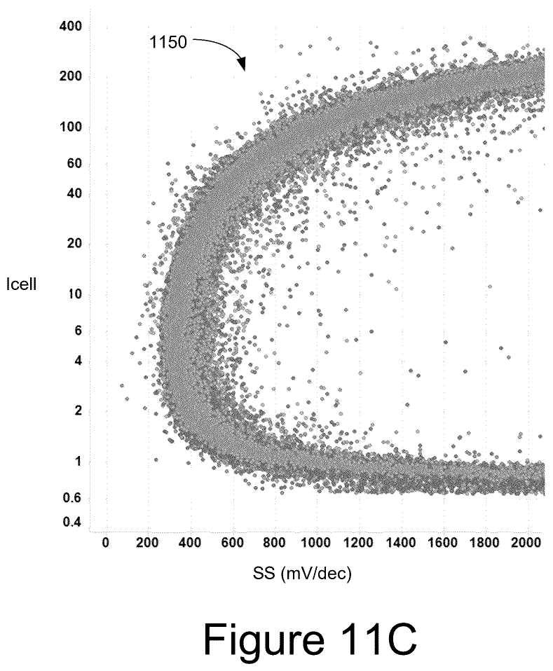

Among the technical challenges of in-compute memory using NAND is achieving narrow current distribution for the current states. A narrow current distribution allows more current states to be placed within a target current range. Moreover, a narrow current distribution improves accuracy of in-memory compute. Referring back to FIGS. 6A and 6B, each Vth distribution has a width due to variability when programming the NAND memory cells. It is desirable for the Vth distributions to have a narrow width. However, there will be some variance in the Vth between the cells programmed to a target Vth state. A similar concept applies to the current states in that a low variance in current is desirable for NAND memory cells programmed to the same current state. FIG. 11A is a graph that illustrates the variance in current for a number of current states. The y-axis is variance (sigma) in the current of the individual memory cells. The x-axis is memory cell current (in a log scale). Each current state has a target current. As an example, the target current could range from 1 nA to 400 nA. Plots 1102, 1104, 1106, 1108, 1110, 1112, and 1114 each show the distribution of currents for a respective current state. For example, plot 1102 shows the distribution of memory cell currents for cells programmed to the lowest current state. The difference between the highest programmed cell current and lowest programmed cell current is referred to herein as ΔIcell, which may be referred to as the width of the current state or alternatively as the NAND cell current distribution. The target current for a current state may be referred to as Itarget. A relevant measure of variance is to divide the current width by the target current (ΔIcell/Itarget). The slope of the plots in FIG. 11A reflects this variance with the lowest current state 1102 having the largest variance (i.e., the highest value of ΔIcell/Itarget). Conversely, the highest current state 1114 has the lowest variance (i.e., the lowest value of ΔIcell/Itarget). It is desirable to have a low variance (i.e., low value of ΔIcell/Itarget). However, the current states with the lowest variance (i.e., the lowest value of ΔIcell/Itarget) have the highest current and hence use the most power. Therefore, it is desirable to provide for low current states that have a low variance (i.e., low value of ΔIcell/Itarget). Embodiments of a NAND memory structure have NAND memory cells that may be programmed to low current states (e.g., sub-threshold region current states) with a low variance (i.e., low value of ΔIcell/Itarget). Therefore, in-memory compute is accurate (due to low variance in the current states) while being power efficient (due to use of sub-threshold current states). Equation 8 describes further details pertaining to the current distribution.

$${σ}_{{I}_{DS}} / {I}_{DS} = {σ}_{{V}_{GS}} / \frac{SS}{ln 10} \qquad Eq . 8$$

The left side of Equation 8 pertains to the current state width ΔIcell/Itarget, but is expressed in terms of I_{DS}. The right side of Equation 8 indicates that a larger sub-threshold switch (SS) can decrease the current state width, which is beneficial.

FIG. 11B is a graph of typical cell current versus Vgs for conventional NAND memory cells that are intended for use to store ECC codewords. Eight plots 1122, 1124, 1126, 1128, 1130, 1132, 1134, and 1136 are depicted for a corresponding eight current states. Each of the eight current states has a different target current for the verify voltage. Each plot is for the NAND cell current versus Vgs. The sub-threshold swing for a given cell current may be obtained from the plots.

FIG. 11C is a graph of cell current versus sub-threshold swing of conventional NAND cells. The graph is based on a composite of the curves in FIG. 11B. The plot 1150 of the sub-threshold swing shows a typical U-shaped behavior. The sub-threshold swing is only about 400 mV/dec in a region of interest. When a NAND memory structure is designed for use for programming ECC code words (as opposed to in-memory compute), the NAND memory cells may have a relatively low sub-threshold swing in a region of interest for low power current states for in-memory compute.

An embodiment of a NAND memory structure targets a sizing scheme between the core dielectric 466 and the cell capacitor dielectric thickness that achieves both a large sub-threshold swing in the NAND memory cells, while maintaining a sufficiently high memory cell capacitor capacitance to help keep the delta Icell low.

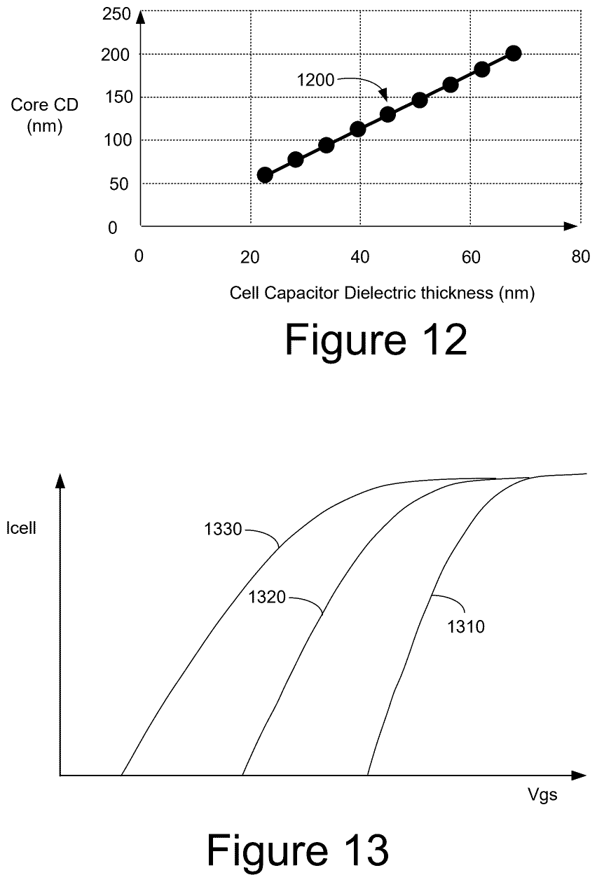

FIG. 12 is a graph showing a relationship between the core dielectric 466 and the cell capacitor dielectric thickness. The plot 1200 shows target combinations of core dielectric 466 and the cell capacitor dielectric thickness to achieve a target memory cell capacitor capacitance. A conventional NAND memory structure may employ a relatively thin cell capacitor dielectric of near 20 nanometers (nm). However, such a thin cell capacitor dielectric (with other typical physical parameters) may not provide a sufficiently high target sub-threshold swing for in-memory compute using NAND memory cells. An embodiment of a NAND memory structure has a much thicker cell capacitor dielectric to help achieve a target sub-threshold swing for in-memory compute. In an embodiment, the cell capacitor dielectric is at least 50 nm in thickness. However, to maintain the desired memory cell capacitor capacitance, the core dielectric 466 may be about 200 nm, assuming the cell capacitor dielectric is about 50 nm thick.

FIG. 13 is a graph of Icell versus Vgs for several different thicknesses of the cell capacitor dielectric. Curve 1310 is for the thinnest cell capacitor dielectric of the three, curve 1320 is for the middle cell capacitor dielectric of the three, and curve 1330 is for the thickest cell capacitor dielectric of the three. The slopes of the three curves indicates that a thicker cell capacitor dielectric leads to a higher sub-threshold swing. As an example, for curve 1310 the cell capacitor dielectric may be about 22 nm, for curve 1320 the cell capacitor dielectric may be about 30 nm, and for curve 1330 the cell capacitor dielectric may be about 37 nm. However, embodiments have even thicker cell capacitor dielectrics than 37 nm, thereby resulting in an even greater sub-threshold swing.

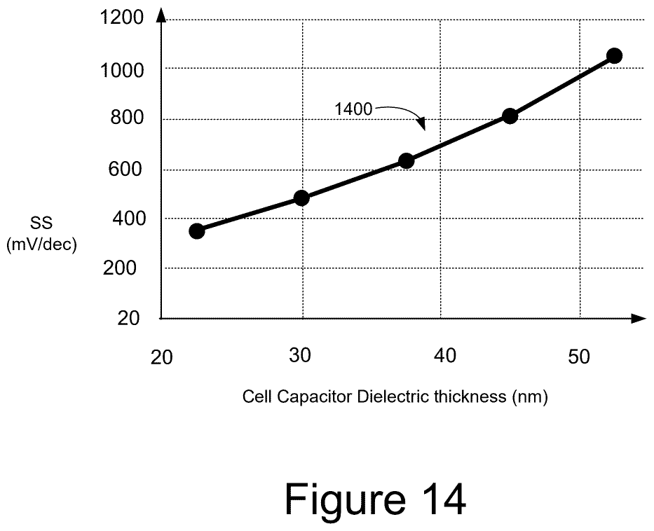

FIG. 14 is a graph of sub-threshold slope versus thickness of the cell capacitor dielectric. Plot 1400 shows that sub-threshold slope increases significantly with thicker cell capacitor dielectric. In an embodiment, the target sub-threshold slope is about 1000 mV/dec. An embodiment of a NAND memory structure with a cell capacitor dielectric of about 50 nm has a sub-threshold slope of at least 1000 mV/dec.

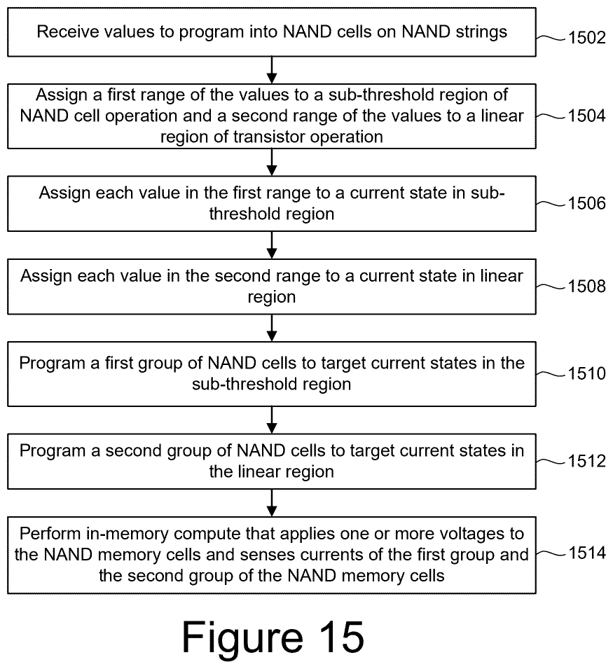

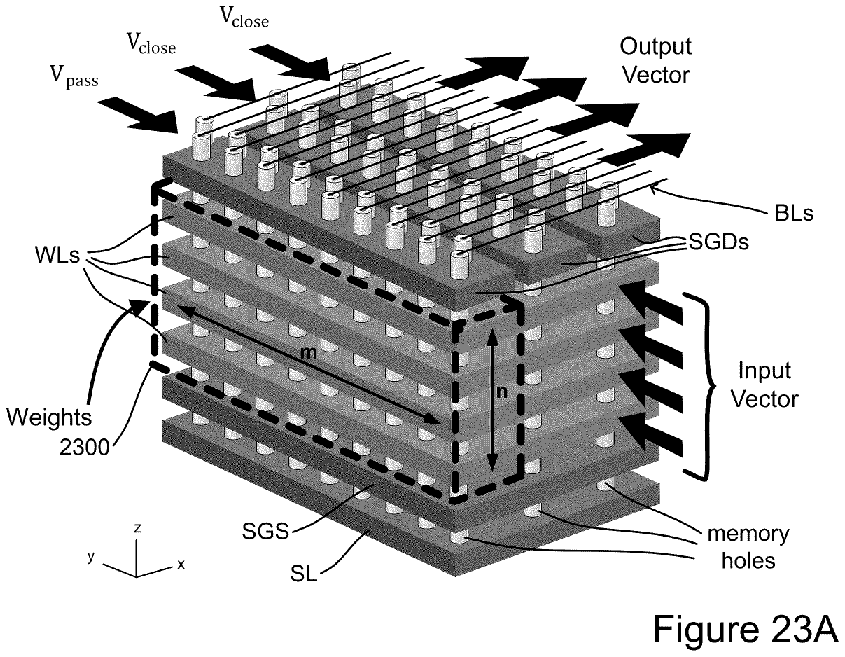

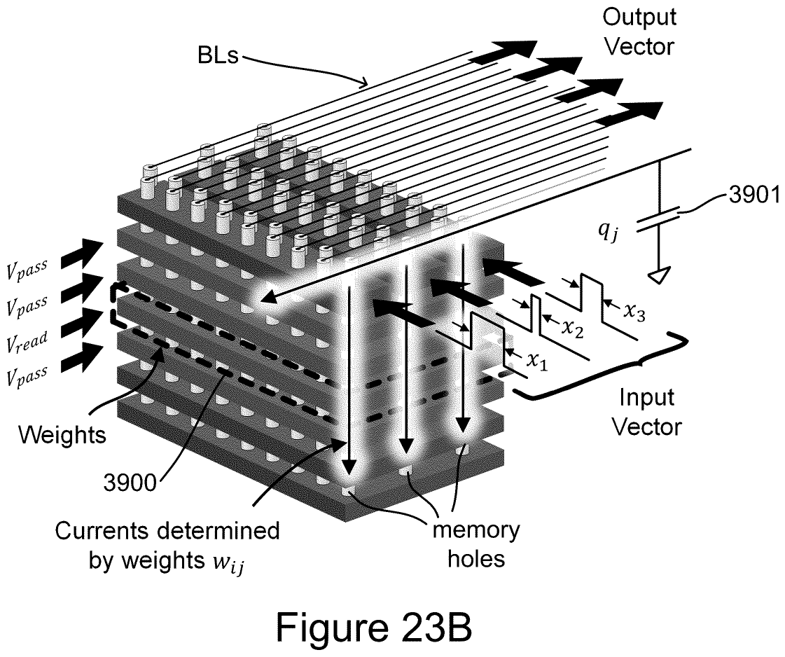

In some embodiment, values are programmed into the NAND cells to allow an in-memory compute to be performed. FIG. 15 is a flowchart of an embodiment of a process of programing NAND cells for in-memory compute, followed by performing the in-memory compute. The process may be performed by a combination of memory controller 120 and/or control circuitry (e.g., system control logic 260, column control circuitry 210, row control circuitry 220) of memory die 200 or control die 211. Steps 1506 and 1508 are shown and described in a particular order as a matter of convenience for discussion. Steps 1506 and 1508 may be performed in a different order. Steps 1506 and 1508 may be performed at the same time. Steps 1514 and 1512 are shown and described in a particular order as a matter of convenience for discussion. Steps 1514 and 1512 may be performed in a different order. Steps 1514 and 1512 may be performed at the same time.
Step 1502 includes receiving values to be programmed into NAND cells. These values may be analog values or digital values. In an embodiment the values include weights of a weight matrix of an artificial neural network.
Step 1504 includes assigning a first range of the values to a sub-threshold region of NAND cell operation and a second range of the values to a linear region of NAND cell operation.
Step 1506 includes assigning each value in the first range to one of the current states in the sub-threshold region. In one technique, the current states are exponentially spaced in the sub-threshold region.
Step 1508 includes assigning each value in the second range to one of the current states in the linear region. In one technique, the current states are linearly spaced in the linear region.
Step 1510 includes programming a first group of the NAND memory cells to target current states in the sub-threshold region. Step 1510 includes applying a verify voltage to the control gates of the memory cells.
Step 1512 includes programming a second group of the NAND memory cells to target current states in the linear region. Step 1512 includes applying the verify voltage to the control gates of the memory cells.
Step 1514 includes performing an in-memory compute that applies one or more voltages to the NAND memory cells and senses currents of the first group and the second group of the NAND memory cells. Different implementations of the in-memory compute are possible. FIGS. 23A and 23B, to be discussed below, show two possible implementations of the in-memory compute. Step 1514 could include using either of those techniques, but is not limited to those techniques. In one embodiment of step 1514 the memory cells that were programmed to the sub-threshold current states have the same verify voltage applied to the control gate as was used to verify the current state. In one embodiment of step 1514 the memory cells that were programmed to the sub-threshold current states a voltage the is close to the verify voltage applied to the control gate. During step 1514 the memory cells that were programmed to the sub-threshold current states operate in the sub-threshold region. In an embodiment, the sub-threshold slope of the memory cells that were programmed to the sub-threshold current states is at least 1000 mV/dec for control gate voltages near the control gate voltage used in step 1514.

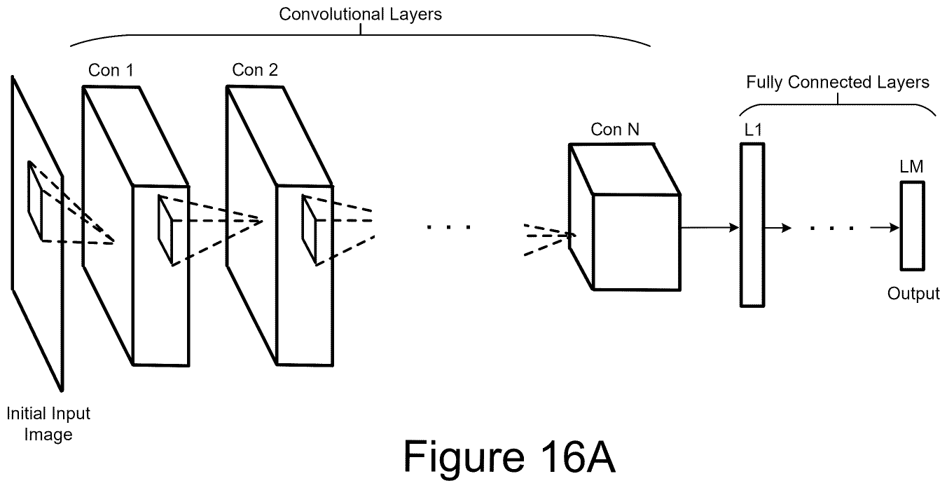

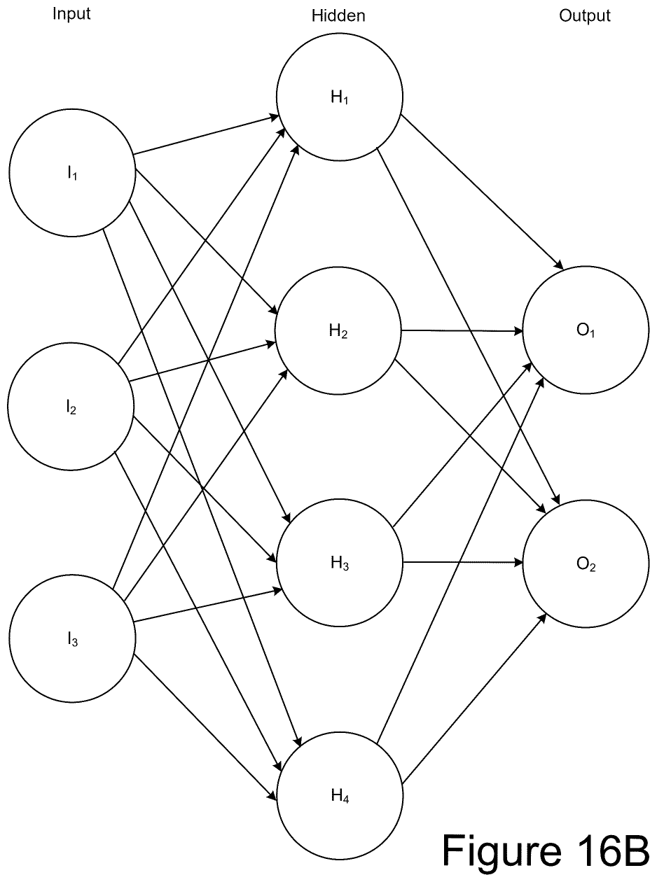

The programming of the NAND cell transistors may be used in the implementation of artificial neural networks. FIG. 16A is a schematic representation of an example of a convolutional neural network (CNN). FIG. 16A illustrates an initial input image of an array of pixel values, followed by a number of convolutional layers that are in turn followed by a number of fully connected layers, the last of which provides the output. Each neuron in the first convolutional layer (Con 1) takes as input data from an n×n pixel sub-region of the input image. The neuron's learned weights, which are collectively referred to as its convolution filter, determine the neuron's single-valued output in response to the input. In the convolutional layers, a neuron's filter is applied to the input image by sliding the input region along the image's x and y dimensions to generate the values of the convolutional layer. In practice, the equivalent convolution is normally implemented by statically identical copies of the neuron to different input regions. The process is repeated through each of the convolutional layers (Con1 to Con N) using each layer's learned weights, after which it is propagated through the fully connected layers (L1 to LM) using their learned weights.

FIG. 16B represents several fully connected layers of a neural network in more detail. In FIG. 16B the shown three layers of the artificial neural network are represented as an interconnected group of nodes or artificial neurons, represented by the circles, and a set of connections from the output of one artificial neuron to the input of another. The example shows three input nodes (I₁, I₂, I₃) and two output nodes (O₁, O₂), with an intermediate layer of four hidden or intermediate nodes (H₁, H₂, H₃, H₄). The nodes, or artificial neurons/synapses, of the artificial neural network are implemented by logic elements of a host or other processing system as a mathematical function that receives one or more inputs and sums them to produce an output. Usually each input is separately weighted and the sum is passed through the node's mathematical function to provide the node's output.

In common artificial neural network implementations, the signal at a connection between nodes (artificial neurons/synapses) is a real number, and the output of each artificial neuron is computed by some non-linear function of the sum of its inputs. Nodes and their connections typically have a weight that adjusts as a learning process proceeds. The weight increases or decreases the strength of the signal at a connection. Nodes may have a threshold such that the signal is only sent if the aggregate signal crosses that threshold. Typically, the nodes are aggregated into layers. Different layers may perform different kinds of transformations on their inputs. Signals travel from the first layer (the input layer), to the last layer (the output layer), possibly after traversing the layers multiple times. Although FIG. 6A shows only a single intermediate or hidden layer, a complex deep neural network (DNN) can have many such intermediate layers.

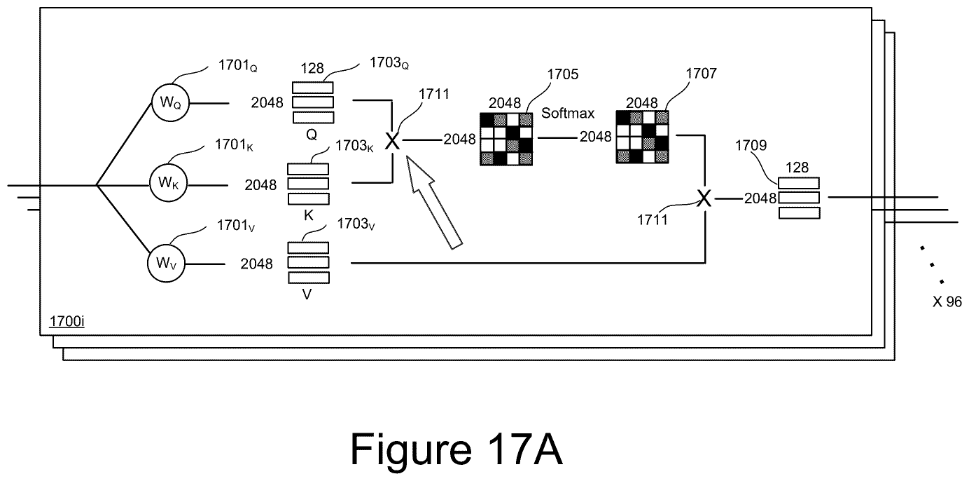

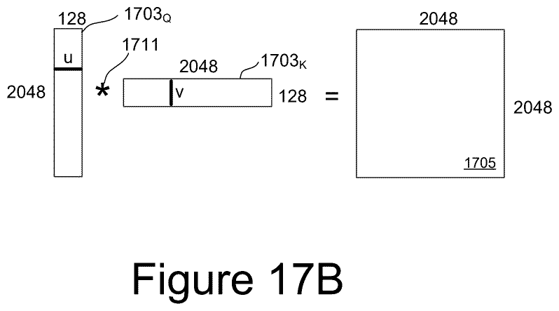

Embodiments of programming memory cell transistors to current states with different spacing between the linear region and the sub-threshold region disclosed herein may be used in a Large Language Model (LLM). Embodiments of programming memory cell transistors to current states disclosed herein may be used in a Generative Pre-trained Transformer (GPT) models of deep neural networks. Some embodiments of programming operations disclosed herein are used for programming in a transformer model of a deep neural network. FIGS. 17A and 17B illustrate some elements of an example of a transformer model of a deep neural network. FIG. 17A shows some of the elements of a layer 1700i of the transformer model, where there can be a large number of these layers, such 96 layers for example. The layer receives as inputs three sets of weights W_{Q} 1701_{Q}, W_{K} 1701_{K}, and W_{V} 1701_{V}, corresponding to Query, Keys and Value matrices of weight values at 1703_{Q}, 1703_{K}, and 1703_{V}. In this example the size of the matrices in 128×2048, which, as represented schematically, can be broken down into vectors. The Query and Key matrices are multiplied at 1711 to generate the 2048×2048 matrix 1705, where all of the sizes here are examples and other embodiments may have different sizes. Various neural network operations, such as Softmax, can be performed on the matrix 1705 to generate the matrix 1707. The output matrix 1709 for the layer is then generated by a multiplication of matrices 1707 and 1703_{V}. FIG. 17B illustrates an embodiment of how the techniques disclosed herein can be applied to the matrix multiplications of FIG. 17A, such as multiplication 1711 indicated by the arrow.

In FIG. 17A, the multiplication of Query, Keys and Value matrices involves values that change for each new computation. FIG. 17B illustrates the multiplication 1711 of the Query matrix 1703_{Q} and Keys matrix 1703_{K}. The Query values are broken down into the u vectors and Keys values broken down into v vectors. The example size of 128 is smaller than the number of NAND word line layers, so that it fits the u vector. As the multiplication identity 1 or other matrix M is only programmed into the NAND array once with either 1 or 0 values, so that there is essentially no wear on the array.

A supervised artificial neural network is “trained” by supplying inputs and then checking and correcting the outputs. For example, a neural network that is trained to recognize dog breeds will process a set of images and calculate the probability that the dog in an image is a certain breed. A user can review the results and select which probabilities the network should display (above a certain threshold, etc.) and return the proposed label. Each mathematical manipulation as such is considered a layer, and complex neural networks have many layers. Due to the depth provided by a large number of intermediate or hidden layers, neural networks can model complex non-linear relationships as they are trained.

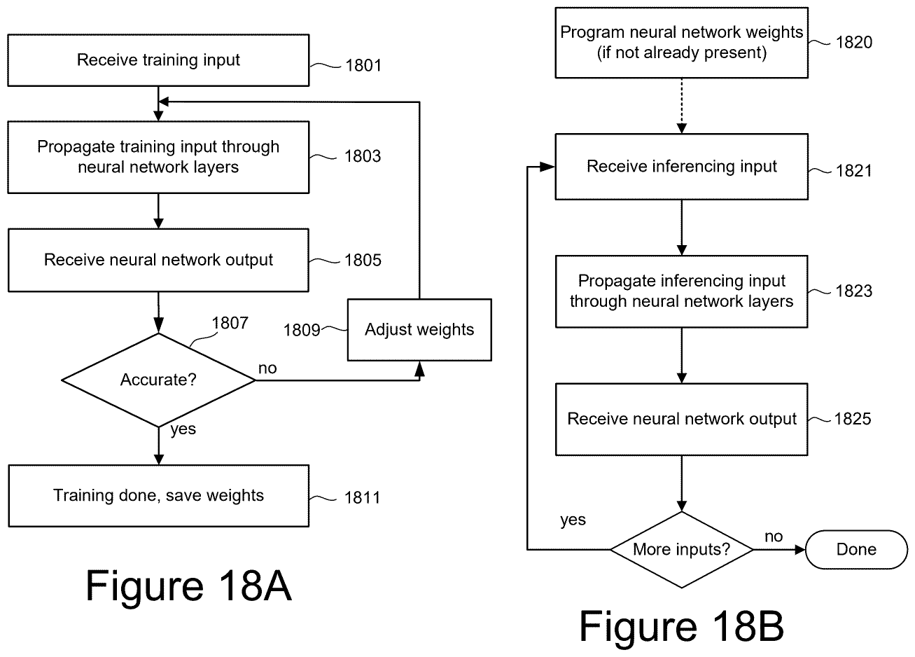

FIG. 18A is a flowchart describing one embodiment of a process for training a neural network to generate a set of weights. The training process is often performed in the cloud, allowing additional or more powerful processing to be accessed. At step 1801, the input, such as a set of images, is received (e.g., the image input in FIG. 16A). At step 1803 the input is propagated through the layers connecting the input to the next layer (e.g., CON1 in FIG. 16A) using the current filter, or set of weights. The neural network's output is then received at the next layer (e.g., CON2 in FIG. 16A) in step 1805, so that the values received as output from one layer serve as the input to the next layer. The inputs from the first layer are propagated in this way through all of the intermediate or hidden layers until they reach the output. In the dog breed example of the preceding paragraph, the input would be the image data of a number of dogs, and the intermediate layers use the current weight values to calculate the probability that the dog in an image is a certain breed, with the proposed dog breed label returned at step 1805. A user can then review the results at step 1807 to select which probabilities the neural network should return and decide whether the current set of weights supply a sufficiently accurate labelling and, if so, the training is complete (step 1811). If the result is not sufficiently accurate, the neural network adjusts the weights at step 1809 based on the probabilities the user selected, followed by looping back to step 1803 to run the input data again with the adjusted weights. Once the neural network's set of weights have been determined, they can be used to “inference,” which is the process of using the determined weights to generate an output result from data input into the neural network. Once the weights are determined at step 1811, they can then be stored in non-volatile memory for later use, where the storage of these weights in non-volatile memory is discussed in further detail below.

FIG. 18B is a flowchart describing a process for the inference phase of supervised learning using a neural network to predict the “meaning” of the input data using an estimated accuracy. Depending on the case, the neural network may be inferenced both in the cloud and by an edge device's (e.g., smart phone, automobile process, hardware accelerator) processor. For example, a considerable portion of the computations of the inference phase may be performed by embodiments of in-memory compute. For example, memory system 100 may perform in-memory compute to perform VMM. In an embodiment, NAND memory is used for the in-memory compute. Step 1820 includes programming neural network weights (if not already present). In an embodiment the neural network weights are programmed into NAND (e.g., 3D NAND). In one embodiment, the host 102 provides the weights to the memory controller 120, which instructs the system control logic 260 to program the neural network weights into storage 130 (e.g., 3D NAND). Step 1820 may include programming NAND memory cells to current states in the linear region and sub-threshold region as described herein. Steps in the process in FIG. 14 may be used in step 1820. Note that the inference phase may be performed many times with these neural network weights. Therefore, in many cases the neural network weights will already be programmed when the inference phase begins.

At step 1821, the input is received, such as the image of a dog in the example used above. As an example, the host 102 may receive the input. At step 1823, the input data is then propagated through the neural network's layers. Step 1823 will be similar to step 1803 of FIG. 18A, but now using the weights established at the end of the training process at step 1811. Step 1823 may include performing in-memory compute to perform, for example, VMM. In an embodiment, the in-memory compute is performed in NAND memory. The memory controller 120 may provide results of the in-memory compute to the host 102. In an embodiment, the host 102 controls the propagation of the data through the neural network's layers. The host 102 may provide input vectors to the memory controller 120, with the memory controller 120 instructing the storage 130 to perform VMM. After propagating the input through the intermediate layers, the output is then provided at step 1825.

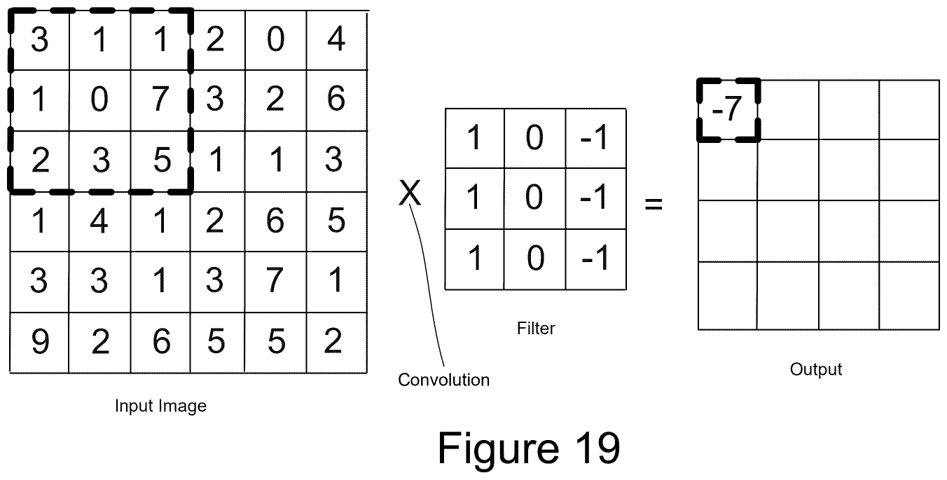

FIG. 19 is a schematic representation of a convolution operation between an input image and filter, or set of weights. In this example, the input image is a 6×6 array of pixel values and the filter is a 3×3 array of weights. The convolution operation is performed by a matrix multiplication of the 3×3 filter with 3×3 blocks of the input image. For example, the multiplication of the upper-left most 3×3 block of the image with the filter results in the top left value of the output matrix. The filter can then be slid across by one pixel on the image to generate the next entry of the output, and so on to generate a top row of 4 elements for the output. By repeating this by sliding the filter down a pixel at a time, the 4×4 output matrix is generated. Similar operations are performed for each of the layers. In a real CNN, the size of the data sets and the number of convolutions performed mean that extremely large numbers of such operations are performed involving very large amounts of data.

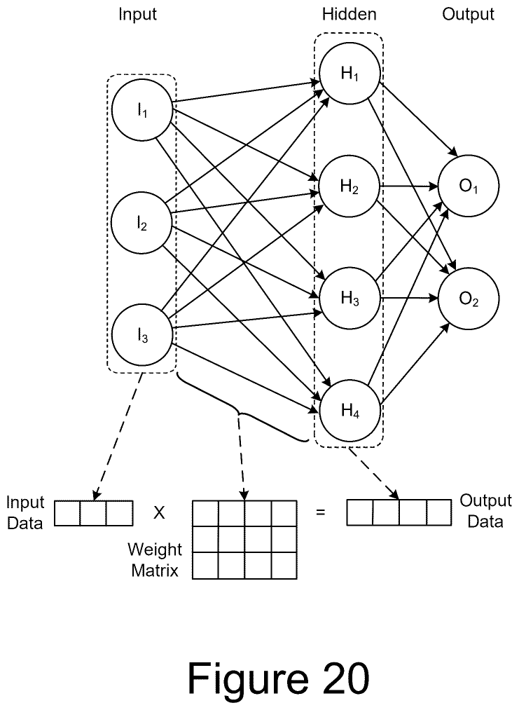

FIG. 20 is a schematic representation of the use of matrix multiplication in a fully connected layer of a neural network. Matrix multiplication, or MatMul, is a commonly used approach in both the training and inference phases for neural networks and is used in kernel methods for machine learning. FIG. 20 at the top is similar to FIG. 16B, where only a single hidden layer is shown between the input layer and the output layer. The input data is represented as a vector of a length corresponding to the number of input nodes. The weights are represented in a weight matrix, where the number of columns corresponds to the number of intermediate nodes in the hidden layer and the number of rows corresponds to the number of input nodes. The output is determined by a matrix multiplication of the input vector and the weight matrix, where each element of the output vector is a dot product of the vector of the input data with a column of the weight matrix.

A common technique for executing the matrix multiplications is by use of a multiplier-accumulator (MAC, or MAC unit). However, this has a number of issues. Referring back to FIG. 18B, the inference phase loads (or programs) the neural network weights at step 1820 before the matrix multiplications are performed by the propagation at step 1823. However, as the amount of data involved can be extremely large, use of a multiplier-accumulator for inferencing has several issues related to the loading of weights. One of these issues is high energy dissipation due to having to use large MAC arrays with the required bit-width. Another issue is high energy dissipation due to the limited size of MAC arrays, resulting in high data movement between logic and memory and an energy dissipation that can be much higher than used in the logic computations themselves.

To help avoid these limitations, the use of a multiplier-accumulator array can be replaced with other memory technologies. For example, the matrix multiplication can be computed within a memory array by leveraging the characteristics of NAND memory and Storage Class Memory (SCM), such as those based on ReRAM, PCM, FeRAM or MRAM based memory cells. This allows for the neural network inputs to be provided via read commands and the neural weights to be preloaded for inferencing. By use of in-memory computing, this can remove the need for logic to perform the matrix multiplication in the MAC array and the need to move data between the memory and the MAC array.

Inferencing in deep neural networks (DNNs) requires large amount of memory and computations, where the computations are usually real number multiplication and accumulations (MACs). Deep neural networks (DNNs), including large language models such as the transformer models are largely linear algebra engines built out of vector-matrix multipliers. Traditional DNNs are inferred on GPU devices, where the large size of DNN models require the GPUs to have a large memories and transfer large amounts of data, with a corresponding high cost. The process-in-memory techniques disclosed herein enable the computations to be implemented using the memory array. Although presented here primarily in the context of a 3D NAND memory, in other embodiments the non-volatile memory can be implemented in other memory technologies, such as ReRAM, MRAM, or PCM. A memory array will have a dynamic range (i.e., the max/min voltage/current it can represent) based on its design and the memory technology used, where a larger dynamic range has better precision and more tolerance to noise.

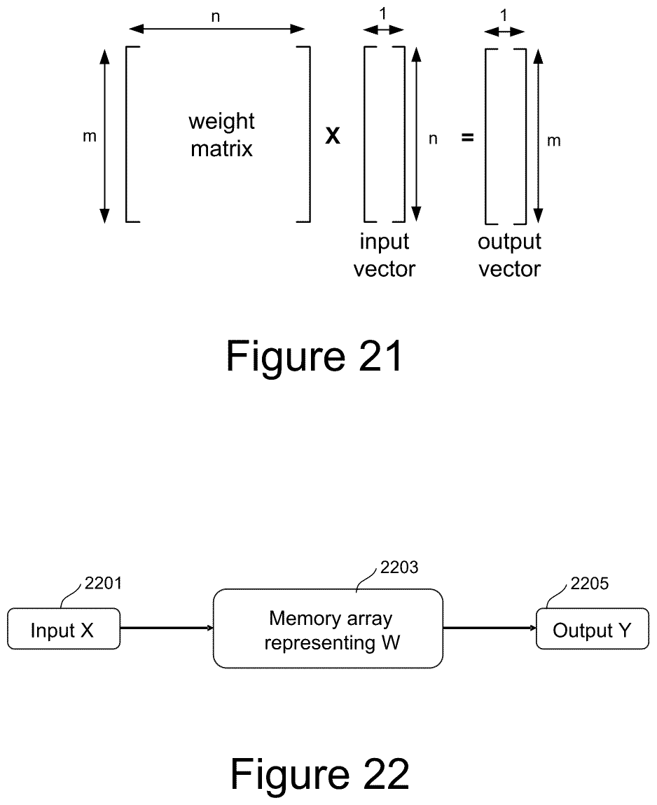

FIGS. 21 and 22 schematically illustrate vector-matrix multiplications, which are a basic computation unit of a DNN, and its implementation using a non-volatile memory array. More specifically, FIG. 21 illustrates the basic idea of a vector-matrix multiplication (VMM). The weight matrix is multiplied by an input vector to generate an output vector. If the input vector X is of size n×1 with components xᵢ, where i runs from 1 to n, and the weight matrix W is of size m×n with components Wⱼⁱ, where j runs from 1 to m, then the output vector Y is of size m×1 with components given by yⱼ=Σᵢ W/xⱼⁱxᵢ.

When implemented through an in-memory computation as illustrated in FIG. 22, the input X 2201 is applied to a set of weights W 2203 to programmed into a memory array to generate an output vector Y 2205. In an analog implementation, input vector X and output vector Y will be analog valued, with the weight values programmed as either analog values or multi-bit digital values. The weight values may be programmed as different current states with different spacing between the linear region and the sub-threshold region as described herein.

FIG. 23A illustrates an embodiment for the multiplication of a vector and a matrix using a 3D NAND structure in which the input vector is applied to the word lines. FIG. 23A shows an abbreviated version of the 3D NAND structure presented above with respect to FIGS. 4-4F, showing four word lines WLs between a lower source side select gate SGS and three drain side select gates SGDs. At the bottom of the 3D NAND structure is a source line (SL). Each SGD may be used to select one sub-block with each sub-block containing a large number of NAND strings. There may be more or fewer than three SGDs per block. For example, FIGS. 4B and 4E depict an example with four SGDs per block. The portion of the 3D NAND structure shown in FIG. 23A may reside within one block. The memory holes run vertically through the horizontal layers and are each connected to a corresponding bit line BL through drain side select gates (SGD). To select a sub-block 2300, the corresponding drain side select gate SGD is biased at Vₚₐₛₛ to turn these gates on, while for the other, non-selected blocks, the SGDs are biased at the off voltage of V_{close}. Note that each bit line connects to one memory hole (NAND string) in each sub-block.

To realize the multiplication of a vector and a matrix (e.g., a set of weights for a neural network), the matrix values (e.g., weights) are programmed into memory cells of a NAND memory, such as sub-block 2300. Programming a weight into a NAND memory cell means that the memory cell is programmed to a target state (e.g., target current) that represents the weight. An embodiment of the memory system 100 converts the weights to target currents. The memory system 100 may perform a calculation to map from the weights to the target currents. Here the NAND memory cell operation refers to the operation when the memory cell is in the target state with the verification voltage applied to its control gate (e.g., the selected word line).

FIG. 23A shows how the memory cells in sub-block 2300 may be programmed to represent an m×n matrix. With some techniques one entry in the weight matrix is represented in a group of two or more cells. In one technique the one entry in the weight matrix is represented by two cells on a first NAND string and two cells on a second NAND string. Thus, the m and n in FIG. 23A refer to the entries in the weight matrix, which is not necessarily the same as the number of cells that are programmed to represent the weight matrix. As one example, n may be about 100 and m may be about 64K. FIG. 23A shows a simplified example with only four cells on each NAND string, but typically there will be many more memory cells on each NAND string. For example, 3D NAND memory can be fabricated to have more than 100 NAND memory cells on a NAND string. It is not required that all memory cells on the NAND string be used to store the weights. FIG. 23A shows 18 NAND strings in the depicted portion of sub-block 2300; however, 3D NAND memory can be fabricated with thousands of NAND strings in a sub-block. As an example, m may be 64K. In one implementation, m NAND strings may be used for the m dimension. In one implementation, 2*m NAND strings may be used for the m dimension. 3D NAND memory can be fabricated to have at least 128K NAND strings in a sub-block. The weights, or other matrix entries, are static and are changed rarely (if at all) in order not to compromise endurance of the NAND memory. The drain side select gate for the selected sub-block (2300 in this example) receives the select gate on voltage Vₚₐₛₛ, while the drain side select gates for unselected blocks are biased at select gate off, or non-select voltage, V_{close}. The input vector, which is dynamic and can change for every new operation, is applied on the word lines of the block. In an embodiment, the memory system 100 converts the values in the input vector to voltages to apply to the word lines. In an embodiment, the voltages that are applied to the word lines to represent the input vector are centered around the verify voltage used to verify the current states. In one embodiment, the voltages that are applied to the word lines represent the input vector comprise a base voltage and an offset, wherein the base voltage is equal to the verify voltage with the offset either adding to or subtracting from the base (verify) voltage. The output vector, corresponding to the product of the input vector and the stored matrix, is then determined based on the signals (e.g., current) on the bit lines. In one technique the difference in current between two bit lines is used to determine a dot product of the input vector and a column of the weight matrix.

FIG. 23B illustrates a timing based method for analog values matrix-vector multiplication. In this example, the input vector is applied to the SGD lines, The set of weights 3900 are programmed into the NAND memory cells. The set of weights 3900 may be programmed into the NAND memory cells as described herein as current states in the linear region and the sub-threshold region. The voltage Vread is applied to the word line connected to the NAND memory cells involved in the calculation. In an embodiment, the voltage Vread has the same magnitude as the voltage used to verify the current states of the memory cells when programming to the linear region current states and the sub-threshold region current states. The output vector is provided on the bit lines, with the output value for a bit line q saved as accumulated charge qⱼ on the capacitor 3901. In this example the analog values of the input vector are encoded as the duration of a high voltage level. FIG. 23B shows three examples of timing-based inputs, x₁>x₃>x₂, where the duration is proportional to the amplitude of the analog value.

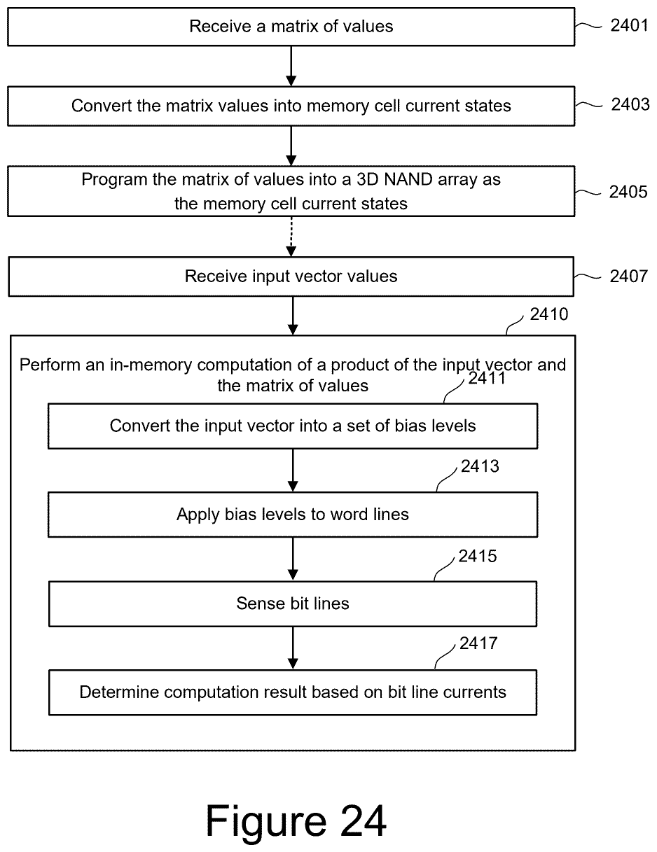

FIG. 24 is a flowchart for an embodiment of operating a 3D NAND multiply and accumulate engine. The process may be performed by a combination of memory controller 120 and/or control circuitry (e.g., system control logic 260, column control circuitry 210, row control circuitry 220) of memory die 200 or control die 211. Beginning at step 2401, a matrix of values is received. The matrix is received, for example, at the memory controller 120 from the host 102. At step 2403, the matrix values are converted to memory cell states for NAND memory cells. An embodiment of the memory controller 120 converts the weights to current states. The memory system 100 may store a table that maps from the weights to the current states. Alternatively, the memory controller 120 may perform a calculation to map from the weights to the current states. In one embodiment, the system control logic 260 converts the weights to current states.

At step 2405 the matrix of values are programmed into the 3D memory array as corrected memory cell states (e.g., current states). The programming may be performed by the control circuitry of memory die 200 or control die 211 in response to an instruction from the memory controller 120. Thus, the memory die control circuitry can then program the matrix into the memory array 202 in step 2405. In some embodiments, the matrix can be pre-programed into the memory array before the memory device shipped to the user.

At step 2407 input vectors are received. In an embodiment, the memory controller 120 receives the input vectors from the host 102. The in-memory multiplication (e.g., VMM) is then performed for an input vector and the matrix of values at step 2410. In one embodiment, the technique depicted in FIG. 23A is used in step 2410. In step 2411 the input vector (x) is converted into a set of bias levels. In one embodiment, the memory controller 120 converts the input vector to bias levels. In one embodiment, the system control logic 260 and/or row decoder 222 converts the input vector values into a corresponding set of bias levels. At step 2413 the bias levels are applied by the array drivers 224 to the word lines. Also in step 2413, a voltage is applied to the SGD of the selected sub-block to turn on this “selected SGD” and a voltage is applied to the SGDs of the unselected sub-block to turn off the “unselected SGDs”. Thus, the NAND channels in the selected sub-block are connected to the bit lines, whereas the NAND channels in the unselected sub-block are cut off from the bit lines Furthermore, the source line may be grounded and the SGS in the selected block has a voltage applied thereto to turn on this SGS to connect the NAND channels to the source line. Additionally, a bit line sensing voltage is applied to the bit lines. An example magnitude for the bit line sensing voltage is about 1.0V as applied to bit line. In step 2415, the bit lines are sensed. At step 2417 a computation result is determined based on the bit line currents.

In the case of Vector-Matrix Multipliers (VMMs), such as when a matrix of values (e.g., weight of a neural network) are programmed into the memory cells of a memory array, the weights can be programmed as analog or multi-bit (e.g., 6- or 8-bit) values. The inputs may then be applied as analog voltage level vertical input vectors on word lines (as in FIG. 23A). Alternatively, the inputs may then be applied on the SGD lines (as in FIG. 23B). Thus, step 2410 in FIG. 24 may be modified to perform a technique depicted in FIG. 23B. In this case, step 2411 may be modified to convert the input vector to timing signals, which are applied to the SGD lines in step 2413.

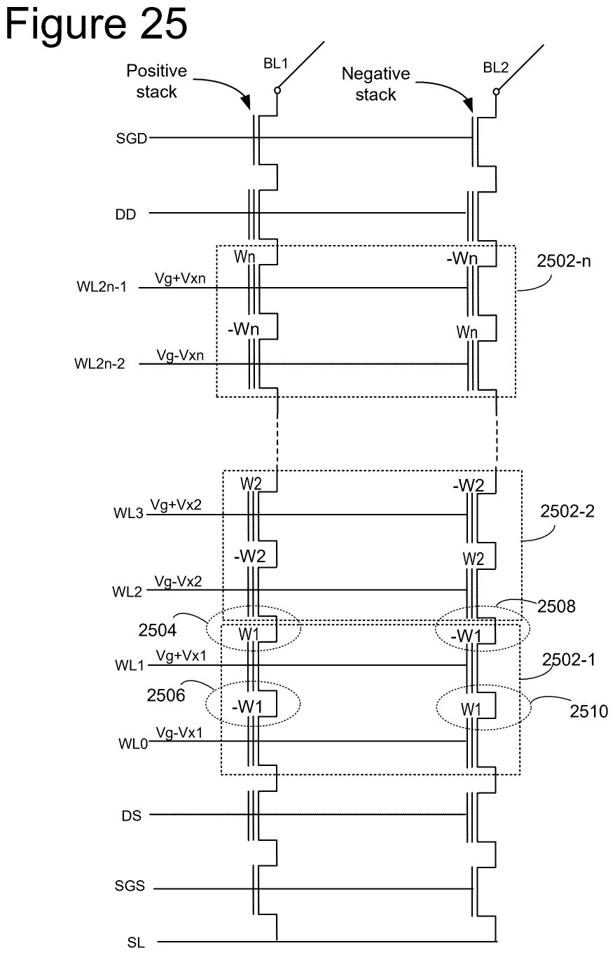

FIG. 25 depicts an example of how memory cells on two NAND strings may be used to store weights in units referred to herein as “calculation cell units.” In an embodiment the NAND strings are fabricated as described herein to achieve a large sub-threshold swing in the NAND cells that are programmed to sub-threshold current states. In an embodiment, the sub-threshold swing when operating the NAND memory cells at currents of the sub-threshold current states is at least 1000 millivolts per decade (mV/dec). In an embodiment, cell capacitor dielectric is at least 50 nm thick and the insulating core 466 is at least 200 nm thick. In an embodiment, the tunneling layer 464 is formed from SiON.

One NAND string will be referred to as the “positive stack” and the other NAND string will be referred to as the “negative stack.” Each calculation cell unit 2502 has two memory cells on the positive stack and two memory cells on the negative stack. FIG. 25 shows an example in which a weight vector is programmed into the memory cells. That is, the weights of one column of the weight matrix are programmed into the two NAND strings. Other pairs of NAND strings will be used to program the weights of other columns of the weight matrix. The memory cells in calculation cell unit 2502-1 are programmed with states to represent W1. The state may be, for example, a current state as described herein. The weight is labeled as either W1 or −W1, where W is a positive value and −W is a negative value having the same absolute value as W. As an example, NAND cell 2504 is programmed with a current state to represent W1, NAND cell 2506 is programmed with a current state to represent-W1, NAND cell 2508 is programmed with a current state to represent W1, and NAND cell 2510 is programmed with a current state to represent-W1. Calculation cell unit 2502-2 is programmed in a similar manner to represent W2 and calculation cell unit 2502-n is programmed in a similar manner to represent Wn. Calculation cell units 2502 for W3 to Wn−1 are not depicted in FIG. 25.

FIG. 25 also shows voltages that are applied to the word lines (and hence control gates of NAND memory cells) to represent the input vector X. The word line voltages are each an offset to a base gate voltage Vg. In an embodiment, the voltage Vg has the same magnitude as the voltage used to verify the current states of the memory cells. There is a positive offset for one word line connected to a particular calculation cell unit 2502 and a negative offset for the other word line connected to the particular calculation cell unit 2502. For example, Vg−Vx1 is applied to WL0 and Vg+Vx1 is applied to WL1. Similarly, Vg−Vx2 is applied to WL2 and Vg+Vx2 is applied to WL3. Also, Vg−Vxn is applied to WL2n−2 and Vg+Vx2n is applied to WL2n−1. In an embodiment, the memory system converts the input vector into the set of voltages applied to the word lines.

Each calculation cell unit 2502 may be used to calculate wᵢ×xᵢ. For example, calculation cell unit 2502-1 may be used to calculate w₁×x₁, calculation cell unit 1502-2 may be used to calculate w₂×x₂ . . . and calculation cell unit 2502-n may be used to calculate wₙ×xₙ. Moreover, collectively the calculation cell units 2502-1 . . . 2502-n may be used for a multiply and accumulate to calculate the product of the input vector and the weight vector. Two resistances may be expressed for each calculation cell unit 2502. Resistance “R⁺” refers to the positive stack portion of the calculation cell unit 2502 (see Eq. 9). Resistance “R⁻” refers to the negative stack portion of the calculation cell unit 2502 (se Eq. 10).

$${R}^{+} = h ( {V}_{g} + {V}_{x} + {V}_{w} ) + h ( {V}_{g} - {V}_{x} - {V}_{w} ) \qquad Eq . 9$$

$${R}^{-} = h ( {V}_{g} + {V}_{x} - {V}_{w} ) + h ( {V}_{g} - {V}_{x} + {V}_{w} ) \qquad Eq . 10$$

In Equations 9 and 10, Vg is a base gate voltage and Vx is an offset that is added or subtracted from the base gate voltage. Also, Vw is the threshold voltage that is used to represent the weight. The R⁺ resistance of each memory cell in the positive stack is in series and the R-resistance of each memory cell in the negative stack is in series. Therefore, the series resistances may be used in a MAC. In practice, the current in each memory cell may be analyzed instead of a direct resistance measurement. Equation 11 shows an expression for the multiplication performed by one calculation unit.

$$x \times w = \frac{f ( ax , bw )}{a \times b \times c} \qquad Eq . 11$$

The numerator in Equation 11 may be expressed as the difference between the current (I⁺) in the positive stack and the current (I⁻) in the negative stack (see Eq. 12).

$$f ( ax , bw ) = {I}^{+} ( ax , bw ) - {I}^{-} ( ax , bw ) \qquad Eq . 12$$

The “a” represents a scale factor or function for the translation from the values in the input vector X and the voltages Vx1, Vx2, . . . Vxn, as shown in Equation 13.

$$Vx = ax \qquad Eq . 13$$

The “b” represents a scale factor or function for the translation from the values in the weight vector to the current states to which the memory cells are programmed (in order to program the weights into the memory cells), as shown in Equation 14.

$$Vw = bw \qquad Eq . 14$$

A scale factor or function c may be used to convert from the current to the resistance. However, another technique is to use a function g(f(ax,bw)) instead of the scale factor c.

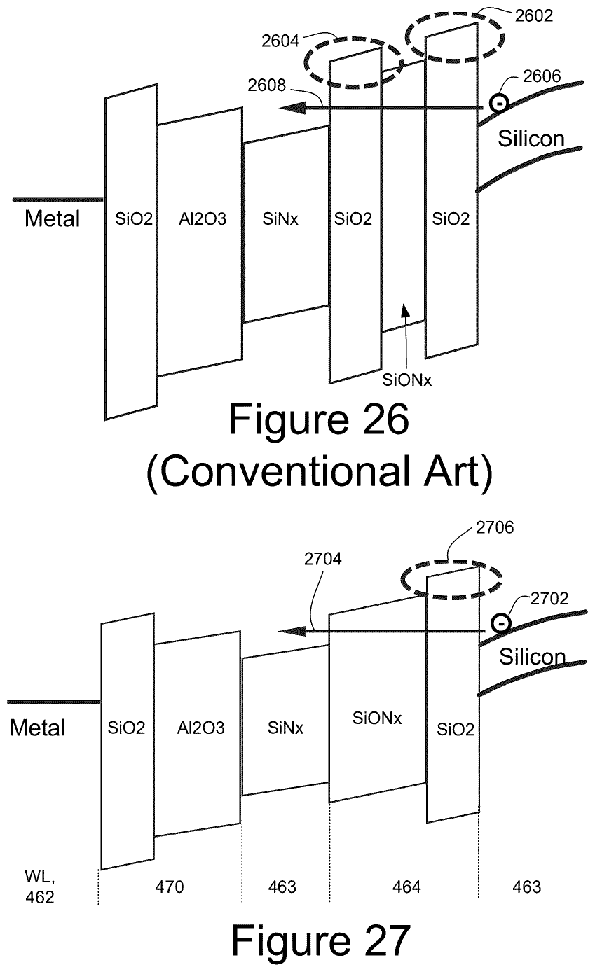

FIG. 26 depicts an energy band diagram of a layers in conventional NAND memory cell. The conventional NAND memory cell has the following layers: Metal (e.g., the word line), SiO2, Al)3 (e.g., a blocking layer), SNx (e.g., charge trapping layer), SiO2, SiONx, SiO2 (e.g., tunneling layer), silicon (e.g., NAND memory cell body or channel). Significantly, the tunneling layer has three materials (SiO2, SiONx, SiO2). An electron 2606 may tunnel from the silicon channel to the SNx charge trapping layer (see arrow 2608) during a program operation. Tunneling may occur in the opposite direction during erase. Each SiO2 region in the tunneling layer presents a significant potential energy barrier to the electron 2606, as indicated by the energy level 2602, 2604 of the two SiO2 regions of the tunneling layer. Such a configuration works well with conventional combined thickness of the tunneling layer, the charge trapping layer, and the blocking layer.

However in some embodiments of a NAND memory structure, the combined thickness of the tunneling layer 464, the charge trapping layer 463, and the blocking layer 470 is a larger than a conventional NAND memory cell (while also increasing the diameter of the insulating core 466) to provide for an increase in sub-threshold swing in the NAND memory cells. The increase in the combined thickness of the tunneling layer 464, the charge trapping layer 463, and the blocking layer 470 could potentially impact programming and/or erase. During program a high voltage may be applied to the word line while the memory cell body may be held at a low voltage. During erase a low voltage may be applied to the word line while the memory cell body may be held at a high voltage. The increase in thickness of the combined thickness of the tunneling layer 464, the charge trapping layer 463, and the blocking layer 470 could potentially require larger program and/or erase voltages to cause electrons 2606 to tunnel through the tunneling layer 464. In some embodiments, the tunneling layer 464 is configured to reduce the potential energy barrier between the silicon channel 466 and the charge trapping layer 463 in to mitigate the additional combined thickness of the tunneling layer 464, the charge trapping layer 463, and the blocking layer 470.

FIG. 27 depicts an energy band diagram of a layers in an embodiment of a NAND memory cell. The NAND memory cell may reside on a NAND string in a three dimensional memory structure such as those depicted in FIGS. 4, and 4B-4F. The embodiment of the NAND memory cell has the following layers: W1, 462 (e.g., metal), blocking layer 470 (e.g., silicon oxide SiO₂; aluminum oxide, Al₂O₃), charge trapping layer 463 (silicon nitride, SiNx), tunneling layer 462 (SiONx, SiO2), NAND memory cell body or channel 463 (silicon). The tunneling layer 464 has only two sub-layers (SiONx, SiO₂) in this embodiment. The sub-layer of SiONx is in direct contact with the SiNx in the charge trap layer 463. The sub-layer of SiONx is in direct contact with the SiO2 in the tunneling layer 464. The sub-layer of SiO₂ in the tunneling layer 464 is in direct contact with the silicon in the channel. An electron 2702 may tunnel from the silicon channel 463 to the SNx charge trapping layer 463 (see arrow 2704) during a program operation. Tunneling may occur in the opposite direction during erase. The energy level 2706 presents a significant barrier to tunneling. However, the SiONx in the tunneling layer 464 directly contacts the charge trapping layer 463 (SiNx) without an intervening SiO₂ layer. With reference again to the conventional NAND cell, there is an intervening SiO₂ layer between the SiONx in the tunneling layer 464 and the charge trapping layer 463, thereby presenting a potential energy barrier due to energy level 2604. Thus, the electron 2702 has less of a potential energy barrier to overcome. Therefore, the program and/or erase voltages can be lowered relative to using thick layers 470, 463, 464 (with a conventional three sub-layer tunneling layer of SiO₂, SiONx, and SiO₂).

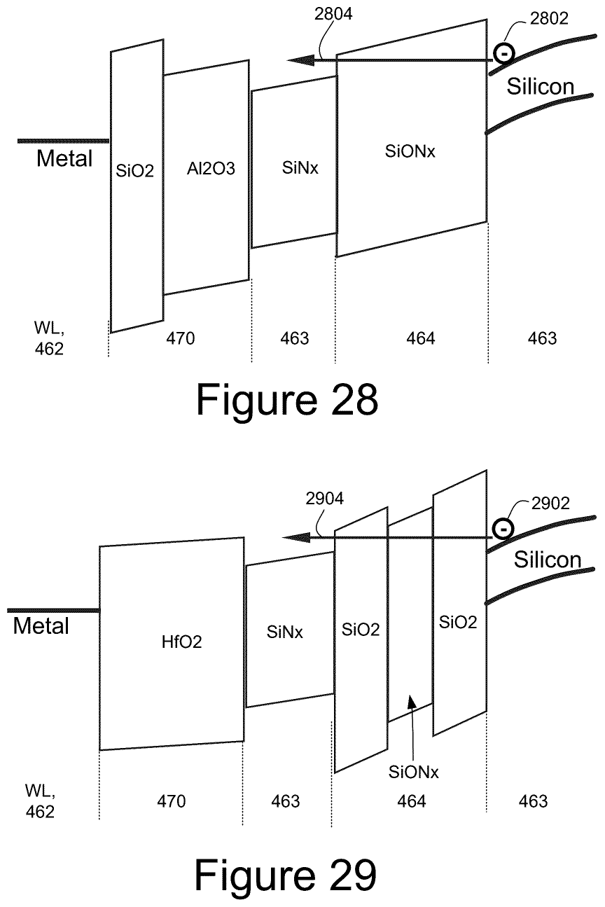

FIG. 28 depicts an energy band diagram of a layers in an embodiment of a NAND memory cell. The NAND memory cell may reside on a NAND string in a three dimensional memory structure such as those depicted in FIGS. 4, and 4B-4F. The embodiment of the NAND memory cell has the following layers: WL 462 (e.g., metal), blocking layer 470 (e.g., SiO₂, Al₂O₃), charge trapping layer 463 (SiNx), tunneling layer 462 (SiONx), NAND memory cell body or channel 463 (silicon). The tunneling layer 464 has only one sub-layers (SiONx) in this embodiment. An electron 2802 may tunnel from the silicon channel 463 to the SiNx charge trapping layer 463 (see arrow 2804) during a program operation. Tunneling may occur in the opposite direction during erase. However, the single SiONx sub-layer in the tunneling layer 464 directly contacts both charge trapping layer 463 (SiNx) without an intervening SiO₂ layer and the silicon body 463 without an intervening SiO₂ layer. With reference again to the conventional NAND cell, there is an intervening SiO₂ layer between the SiONx in the tunneling layer 464 and the charge trapping layer 463 and also intervening SiO₂ layer between the SiONx in the tunneling layer 464 and the silicon (e.g., body), thereby presenting two potential energy barriers due to energy levels 2602, 2604. Thus, the electron 2802 in FIG. 28 has less of a potential energy barrier to overcome relative to the conventional tunnelling barrier. Therefore, the program and/or erase voltages can be lowered relative to using thick layers 470, 463, 464 (with a conventional three sub-layer tunneling layer of SiO₂, SiONx, and SiO₂).

One embodiment of a NAND memory structure modifies the blocking layer to mitigate the additional combined thickness of the tunneling layer 464, the charge trapping layer 463, and the blocking layer 470. FIG. 29 depicts an energy band diagram of a layers in an embodiment of a NAND memory cell. The NAND memory cell may reside on a NAND string in a three dimensional memory structure such as those depicted in FIGS. 4, and 4B-4F. The embodiment of the NAND memory cell has the following layers: WL, 462 (e.g., metal), blocking layer 470 (hafnium oxide, HfO₂), charge trapping layer 463 (SiNx), tunneling layer 462 (e.g., SiO₂, SiONx, SiO₂), NAND memory cell body or channel 463 (silicon). The blocking layer 470 has a layer of HfO₂ in this embodiment. Note that in an embodiment such as in FIG. 28, the blocking layer 470 has two sub-layers (SiO₂, Al₂O₃). The HfO₂ in blocking layer 470 in FIG. 29 has a significantly larger dielectric constant than the dielectric constant of the blocking layer 470 having two sub-layers (SiO₂, Al₂O₃). The high-k dielectric constant of the HfO₂ in blocking layer 470 increases the ratio of the program voltage (or the erase voltage) dropped across on tunnelling layer 464, thereby enhancing the tunneling electric field and current.

In FIG. 29, the tunneling layer 464 has three sub-layers (SiO₂, SiONx, SiO₂), with electron 2902 tunneling through (arrow 2904). However, the materials used in the tunneling layer 464 in FIG. 28 (single SiONx layer) or the tunneling layer 464 in FIG. 27 (two sub-layers SiO2, SiONx) may be substituted into the tunneling layer 464 in FIG. 29.

In view of the foregoing, an embodiment includes an apparatus comprising a memory structure having alternating conductive layers and insulating layers. The memory structure has NAND strings extending perpendicular through the alternating conductive layers and insulating layers. Each NAND string has a plurality of NAND memory cell transistors. Each NAND string has: an insulating core having a diameter of at least 150 nm and memory cell films that separate the insulating core from the conductive layers and insulating layers. The memory cell films include: a channel layer adjacent and surrounding the insulating core; a tunnelling layer adjacent and surrounding to the channel layer; a charge trap layer adjacent and surrounding to the tunnelling layer; and a blocking layer adjacent and surrounding to the charge trap layer. The blocking layer is adjacent to the alternating conducting layers and insulating layers. A combined thickness of the tunnelling layer, the charge trap layer, and the blocking layer is at least 50 nm.

In a further embodiment of the apparatus a ratio of the diameter of the insulating core to the combined thickness of the tunnelling layer, the charge trap layer, and the blocking layer is approximately 3:1.

In a further embodiment of the apparatus, the charge trap layer comprises a layer of SiNx; the tunnelling layer comprises a layer of SiONx in direct contact with the layer of the SiNx of the charge trap layer; and the channel layer comprises silicon.

In a further embodiment of the apparatus, the layer of SiONx in is direct contact with the silicon of the channel layer.

In a further embodiment of the apparatus, the tunnelling layer further comprises a layer of silicon oxide in direct contact with both the layer of SiONx of the tunnelling layer and the silicon of the channel layer.

In a further embodiment of the apparatus, the insulating core comprises silicon oxide In a further embodiment of the apparatus, the blocking layer comprises hafnium oxide

In a further embodiment of the apparatus, the blocking layer comprises aluminum oxide and silicon oxide.

In a further embodiment, the apparatus further comprises one or more control circuits configured to convert a set of numerical values to a plurality of current states. The plurality of current states including sub-threshold current states for which a magnitude of the current corresponds to a sub-threshold region of operation of the NAND memory cell transistors. The one or more control circuits are configured to program the NAND memory cell transistors to the plurality of current states in order to program values in the set into the NAND memory cell transistors. The one or more control circuits are configured to perform an in-memory compute operation using the programmed NAND memory cell transistors.

In a further embodiment of the apparatus a sub-threshold slope of the NAND memory cell transistors when operated at the sub-threshold current states is at least 1000.

An embodiment includes a NAND memory system, comprising a three dimensional NAND memory structure having alternating word line layers and insulating layers. The three dimensional NAND memory structure have NAND strings formed in memory holes that extend perpendicularly through the alternating word line layers and insulating layers. Each NAND string ha a plurality of NAND memory cell transistors. Each memory hole comprises: an insulating core; a silicon channel adjacent and surrounding the insulating core; a tunnelling layer adjacent and surrounding to the silicon channel, wherein the tunnelling layer comprises a layer of SiONx; a charge trap layer adjacent and surrounding to the tunnelling layer, the charge trap layer comprising silicon nitride in direct contact with the SiONx of the tunnelling layer; and a blocking oxide layer adjacent and surrounding to the charge trap layer, the blocking oxide layer adjacent to the alternating word line layers and insulating layers.

An embodiment includes a computation device, comprising a three dimensional NAND memory structure having alternating conducting layers and insulating layers. The three dimensional NAND memory structure has NAND strings extending perpendicularly through the alternating conducting layers and insulating layers. Each NAND string has a plurality of NAND memory cells. The computation device comprises one or more control circuits in communication with the three dimensional NAND memory structure. The one or more control circuits are configured to convert a set of numerical values to current states, wherein the current states include linear current states that correspond to linear region operation of the NAND memory cells and sub-threshold current states that correspond to sub-threshold region operation of the NAND memory cells. The one or more control circuits are configured to program the NAND memory cells to the current states in order to program the set of numerical values into the NAND memory cells. The one or more control circuits are configured to perform an in-memory compute operation using the programmed NAND memory cells, wherein a sub-threshold slope of the NAND memory cells programmed to the sub-threshold current states is at least 1000 during the in-memory compute.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
a memory structure having alternating conductive layers and insulating layers, the memory structure having NAND strings extending perpendicular through the alternating conductive layers and insulating layers, each NAND string having a plurality of NAND memory cell transistors, each NAND string having:
an insulating core, the insulating core having a diameter of at least 150 nm;
memory cell films that separate the insulating core from the conductive layers and insulating layers, the memory cell films including:
a channel layer adjacent and surrounding the insulating core;
a tunnelling layer adjacent and surrounding to the channel layer;
a charge trap layer adjacent and surrounding to the tunnelling layer; and
a blocking layer adjacent and surrounding to the charge trap layer, the blocking layer adjacent to the alternating conducting layers and insulating layers, wherein a combined thickness of the tunnelling layer, the charge trap layer, and the blocking layer is at least 50 nm.

2. The apparatus of claim 1, wherein a ratio of the diameter of the insulating core to the combined thickness of the tunnelling layer, the charge trap layer, and the blocking layer is approximately 3:1.

3. The apparatus of claim 1, wherein:
the charge trap layer comprises a layer of SiNx;
the tunnelling layer comprises a layer of SiONx in direct contact with the layer of the SiNx of the charge trap layer; and
the channel layer comprises silicon.

4. The apparatus of claim 3, wherein the layer of SiONx in is direct contact with the silicon of the channel layer.

5. The apparatus of claim 3, wherein the tunnelling layer further comprises a layer of silicon oxide in direct contact with both the layer of SiONx of the tunnelling layer and the silicon of the channel layer.

6. The apparatus of claim 1, wherein the insulating core comprises silicon oxide.

7. The apparatus of claim 1, wherein the blocking layer comprises hafnium oxide.

8. The apparatus of claim 1, wherein the blocking layer comprises aluminum oxide and silicon oxide.

9. The apparatus of claim 1, further comprising one or more control circuits configured to:
convert a set of numerical values to a plurality of current states, the plurality of current states including sub-threshold current states for which a magnitude of the current corresponds to a sub-threshold region of operation of the NAND memory cell transistors;
program the NAND memory cell transistors to the plurality of current states in order to program values in the set into the NAND memory cell transistors; and
perform an in-memory compute operation using the programmed NAND memory cell transistors.

10. The apparatus of claim 9, wherein a sub-threshold slope of the NAND memory cell transistors when operated at the sub-threshold current states is at least 1000.

11. A NAND memory system, comprising:
a three dimensional NAND memory structure having alternating word line layers and insulating layers, the three dimensional NAND memory structure having NAND strings formed in memory holes that extend perpendicularly through the alternating word line layers and insulating layers, each NAND string having a plurality of NAND memory cell transistors, each memory hole comprising:
an insulating core;
a silicon channel adjacent and surrounding the insulating core;
a tunnelling layer adjacent and surrounding to the silicon channel, wherein the tunnelling layer comprises a layer of SiONx;
a charge trap layer adjacent and surrounding to the tunnelling layer, the charge trap layer comprising silicon nitride in direct contact with the SiONx of the tunnelling layer; and
a blocking oxide layer adjacent and surrounding to the charge trap layer, the blocking oxide layer adjacent to the alternating word line layers and insulating layers.

12. The NAND memory system of claim 11, wherein the tunnelling layer comprises a single layer of the SiONx in direct contact with both the silicon nitride of the charge trap layer and the silicon channel.

13. The NAND memory system of claim 11, wherein the tunnelling layer comprises the layer of the SiONx in direct contact the silicon nitride of the charge trap layer and a layer of SiO2 in direct contact with the silicon channel, the layer of SiO2 is in direct contact with the layer of the SiONx.

14. The NAND memory system of claim 11, wherein the blocking oxide layer comprises hafnium oxide.

15. The NAND memory system of claim 11, further comprising one or more control circuits configured to:
convert a set of numerical values to a corresponding plurality of sub-threshold current states for which a magnitude of the current corresponds to a sub-threshold region of operation of the NAND memory cell transistors;
program the NAND memory cell transistors to the sub-threshold current states in order to program the set of numerical values into the NAND memory cell transistors; and
perform an in-memory compute operation using the programmed NAND memory cell transistors.

16. The NAND memory system of claim 15, wherein a sub-threshold slope of the NAND memory cell transistors when operated at the sub-threshold current states is at least 1000.

17. A computation device, comprising:
a three dimensional NAND memory structure having alternating conducting layers and insulating layers, the three dimensional NAND memory structure having NAND strings extending perpendicularly through the alternating conducting layers and insulating layers, each NAND string having a plurality of NAND memory cells; and
one or more control circuits in communication with the three dimensional NAND memory structure, wherein the one or more control circuits are configured to:
convert a set of numerical values to current states, wherein the current states include linear current states that correspond to linear region operation of the NAND memory cells and sub-threshold current states that correspond to sub-threshold region operation of the NAND memory cells;
program the NAND memory cells to the current states in order to program the set of numerical values into the NAND memory cells; and
perform an in-memory compute operation using the programmed NAND memory cells, wherein a sub-threshold slope of the NAND memory cells programmed to the sub-threshold current states is at least 1000 during the in-memory compute.

18. The computation device of claim 17, wherein each NAND string comprises:
an insulating core, the insulating core having a diameter of at least 150 nm;
a silicon channel adjacent and surrounding the insulating core;
a tunnelling layer adjacent and surrounding to the silicon channel;
a charge trap layer adjacent and surrounding to the tunnelling layer; and
a blocking oxide layer adjacent and surrounding to the charge trap layer, the blocking oxide layer adjacent to the alternating conducting layers and insulating layers, wherein a combined thickness of the tunnelling layer, the charge trap layer, and the blocking oxide layer is at least 50 nm, and wherein a ratio of the diameter of the insulating core to the combined thickness of the tunnelling layer, the charge trap layer, and the blocking oxide layer is approximately 3:1.

19. The computation device of claim 17, wherein each NAND string comprises:
an insulating core;
a silicon channel adjacent and surrounding the insulating core;
a tunnelling layer adjacent and surrounding to the silicon channel, the tunneling layer comprises a layer of SiONx;
a charge trap layer adjacent and surrounding to the tunnelling layer, the charge trap layer comprises a layer of SiNx in direct contact with the layer of SiONx of the tunnelling layer; and
a blocking oxide layer adjacent and surrounding to the charge trap layer, the blocking oxide layer adjacent to the alternating conducting layers and insulating layers.

20. The computation device of claim 17, wherein each NAND string comprises:
an insulating core;
a silicon channel adjacent and surrounding the insulating core;
a tunnelling layer adjacent and surrounding to the silicon channel;
a charge trap layer adjacent and surrounding to the tunnelling layer; and
a blocking oxide layer adjacent and surrounding to the charge trap layer, the blocking oxide layer adjacent to the alternating conducting layers and insulating layers, the blocking oxide layer comprises hafnium oxide.
